(19) United States
(12) Patent Application Publication
(10) Pub. No.: US 2024/0237460 A1
(43) Pub. Date: Jul. 11, 2024

(54) DISPLAY DEVICE

(71) Applicant: Samsung Display Co., Ltd., Yongin-si, Gyeonggi-do (KR)

(72) Inventors: Yong Hwan PARK, Yongin-si (KR); Ju Yeon KIM, Yongin-si (KR); Sung Kyun PARK, Yongin-si (KR); Seung Chan LEE, Yongin-si (KR); Sae Young HONG, Yongin-si (KR)

(21) Appl. No.: 18/501,889

(22) Filed: Nov. 3, 2023

(30) Foreign Application Priority Data
Jan. 6, 2023 (KR) 10-2023-0002475
Mar. 24, 2023 (KR) 10-2023-0038911

(51) Int. Cl. H10K 59/35; H10K 59/131; H10K 59/40; H10K 59/88; H10K 71/00

(52) U.S. Cl. CPC H10K 59/353; H10K 59/131; H10K 59/40; H10K 59/88; H10K 71/621

(57) ABSTRACT

A display device includes: a display component comprising first and second pixels; and a sensor component comprising conductive patterns. Each pixel may include first, second and third sub-pixels. The first and second pixels may be adjacent to each other. The third sub-pixel of the first pixel may be adjacent to the third sub-pixel of the second pixel. The first and second sub-pixels of the first pixel may be adjacent to the first and second sub-pixels of the second pixel. Each conductive pattern may comprise first and second sensing electrodes. The first sensing electrode may comprise first cells and a first bridge. The second sensing electrode may comprise second cells and a second bridge. The second bridge may be between the third sub-pixels of the first and second pixels, and between the second sub-pixel of the first pixel and the first sub-pixel of the second pixel.

### CROSS-REFERENCE TO RELATED APPLICATIONS

The present application claims priority to and benefits of Korean Patent Application No. 10-2023-0002475 filed on Jan. 06, 2023 and Korean Patent Application No. 10-2023-0038911 filed on Mar. 24, 2023, in the Korean Intellectual Property Office, the entire disclosure of each of which is incorporated herein by reference.

### BACKGROUND

### 1. Field

Aspects of some embodiments of the present disclosure relate to a display device.

### 2. Description of Related Art

With the development of information technology, the importance of a display device, which provides a connection medium between users and information, has been emphasized. The display device may comprise a light emitting element.

A structure for improving external visibility may be desirable to improve display quality of the display device. For example, there is a need to adjust external light reflectivity to improve the external visibility.

The above information disclosed in this Background section is only for enhancement of understanding of the background and therefore the information discussed in this Background section does not necessarily constitute prior art.

### SUMMARY

Various embodiments of the disclosure are directed to a display device having relatively improved visibility.

Aspects of some embodiments of the present disclosure may include a display device including: a display component formed on a base layer, and provided to form a plurality of pixels comprising a first pixel and a second pixel; and a sensor component on the display component, and comprising conductive patterns comprising a first conductive pattern and a second conductive pattern. Each of the plurality of pixels may comprise sub-pixels comprising: a first sub-pixel forming a first sub-pixel area from which a first color of light is provided; a second sub-pixel forming a second sub-pixel area from which a second color of light is provided; and a third sub-pixel forming a third sub-pixel area from which a third color of light is provided. The first pixel and the second pixel may be adjacent to each other in a first direction. The third sub-pixel of the first pixel may be adjacent to the third sub-pixel of the second pixel in the first direction. The first sub-pixel and the second sub-pixel of the first pixel may be adjacent to the first sub-pixel and the second sub-pixel of the second pixel in the first direction. Each of the conductive patterns may comprise a first sensing electrode and a second sensing electrode. The first sensing electrode may comprise first cells, and a first bridge electrically connecting the first cells. The second sensing electrode may comprise second cells, and a second bridge electrically connecting the second cells. A portion of the second bridge may be between the third sub-pixel of the first pixel and the third sub-pixel of the second pixel, and another portion of the second bridge may be between the second sub-pixel of the first pixel and the first sub-pixel of the second pixel.

According to some embodiments, the second conductive pattern may comprise first portions and a second portion. Each of the first portions may form a loop enclosing one or more of the sub-pixels, and the second portion may connect the first portions to each other.

According to some embodiments, the second bridge overlaps the second portion, in a plan view.

According to some embodiments, the second bridge may be electrically connected to the second conductive pattern through a contactor. The contactor may overlap the third sub-pixel in the first direction.

According to some embodiments, the second bridge may pass between the first sub-pixel and the second sub-pixel, and pass between the second sub-pixel of the first pixel and the second sub-pixel of the first pixel.

According to some embodiments, the second bridge may extend in a second direction different from the first direction.

According to some embodiments, the entirety of an end of the first conductive pattern may be covered with an end of the second conductive pattern, in a plan view.

According to some embodiments, a first width of a portion of the second conductive pattern that does not overlap the first conductive pattern may be less than a second width of another portion of the second conductive pattern that overlaps the first conductive pattern.

According to some embodiments, a surface area of the third sub-pixel area may be greater than a surface area of the first sub-pixel area or a surface area of the second sub-pixel area.

According to some embodiments, the third sub-pixels for the respective sub-pixels may be spaced apart from each other at regular intervals in the first direction.

According to some embodiments, the third sub-pixels may be spaced apart from each other by a first distance in a first area, and other third sub-pixels may be spaced apart from each other by a second distance in a second area adjacent to the first area in the first direction.

According to some embodiments, the second bridge may be electrically connected to the first conductive pattern through a contactor. The contactor may be in the second area.

According to some embodiments, the second bridge may comprise a bent portion, and one or more unit bridges extending in different directions and between the sub-pixels.

According to some embodiments, the first sensing electrode and the second sensing electrode may be spaced apart from each other with a separation line interposed therebetween. A shape formed by the unit bridges may correspond to a shape of the separation line.

According to some embodiments, the first conductive pattern may form dummy bridges each of which is identical in one or more of a shape, a length, and an extension direction to the second bridge.

According to some embodiments, distances by which adjacent bridges among the dummy bridges and the second bridge are spaced apart from each other in the first direction may be identical to each other.

According to some embodiments, the dummy bridge may comprise a first dummy bridge and a second dummy bridge. The first dummy bridge may be electrically connected to the second conductive pattern. The second dummy bridge may be electrically separated from the second conductive pattern.

According to some embodiments, the first dummy bridge may be in an internal area of one of the first sensing electrode or the second sensing electrode. The second dummy bridge may be on the first sensing electrode and the second sensing electrode.

According to some embodiments, the display device may further comprise a cutting area in which at least a portion of the second conductive pattern is cut, in an area where the first cell or the second cell is formed.

According to some embodiments of the present disclosure a display device includes: a pixel formed on a base layer, and comprising a first sub-pixel configured to emit a first color of light, a second sub-pixel configured to emit a second color of light, and a third sub-pixel configured to emit a third color of light; and a sensor component comprising a conductive pattern comprising a first conductive pattern and a second conductive pattern on the first conductive pattern. The first sub-pixel and the second sub-pixel may be alternately arranged along a first direction to form a first pixel column. The second sub-pixel may be successively arranged along the first direction to form a second pixel column. The first pixel column and the second pixel column may be alternately arranged along a second direction different from the first direction. The conductive pattern may form sensing electrodes. The first conductive pattern may be more adjacent to the base layer than is the second conductive pattern. The sensing electrodes may comprise cells formed by the second conductive pattern, and a bridge formed by the first conductive pattern and configured to electrically connect the cells to each other. The third sub-pixel may comprise third sub-pixels adjacent to each other. The bridge may extend, in a plan view, in the first direction between the third sub-pixels adjacent to each other and between the first sub-pixel and the second sub-pixel.

### BRIEF DESCRIPTION OF THE DRAWINGS

FIG. 1 is a view for describing a display device according to some embodiments.

FIG. 2 is a schematic sectional view for describing a stacked structure of the display device according to some embodiments.

FIG. 3 is a schematic sectional view illustrating a display component according to some embodiments.

FIG. 4 is a schematic sectional view illustrating a sensing component according to some embodiments.

FIG. 5 is a schematic plan view illustrating sensing electrodes according to some embodiments.

FIG. 6 is a schematic sectional view illustrating a sensing component according to some embodiments.

FIGS. 7 and 8 are schematic sectional views each illustrating a display device according to some embodiments.

FIGS. 9 to 15 are schematic plan views each illustrating a display device according to some embodiments.

FIGS. 16 to 20 are schematic sectional views each illustrating the display device according to some embodiments.

FIGS. 21 and 22 are schematic views each illustrating a display device according to some embodiments.

FIGS. 23 and 29 are schematic views each illustrating a display device according to some embodiments.

FIGS. 30 to 32 are schematic views each illustrating a display device according to some embodiments.

FIGS. 33 to 35 are schematic views each illustrating a display device according to some embodiments.

FIGS. 36 to 38 are schematic views each illustrating the display device according to some embodiments.

### DETAILED DESCRIPTION

As the disclosure allows for various changes and numerous embodiments, particular embodiments will be illustrated in the drawings and described in detail in the written description. However, this is not intended to limit the disclosure to particular modes of practice, and it is to be appreciated that all changes, equivalents, and substitutes that do not depart from the spirit and technical scope of the disclosure are encompassed in the disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element. In the disclosure, the singular forms are intended to comprise the plural forms as well, unless the context clearly indicates otherwise.

It will be further understood that the terms “comprise”, “comprise”, “have”, etc. when used in the disclosure, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is located on a second part, the first part may be not only directly on the second part but a third part may intervene between them. In addition, when it is expressed that a first part such as a layer, a film, a region, or a plate is formed on a second part, the surface of the second part on which the first part is formed is not limited to an upper surface of the second part but may comprise other surfaces such as a side surface or a lower surface of the second part. To the contrary, in case that a first part such as a layer, a film, a region, or a plate is under a second part, the first part may be not only directly under the second part but a third part may intervene between them.

Various embodiments of the disclosure relates to a display device. Hereinafter, a display device according to some embodiments will be described in more detail with reference to the attached drawings.

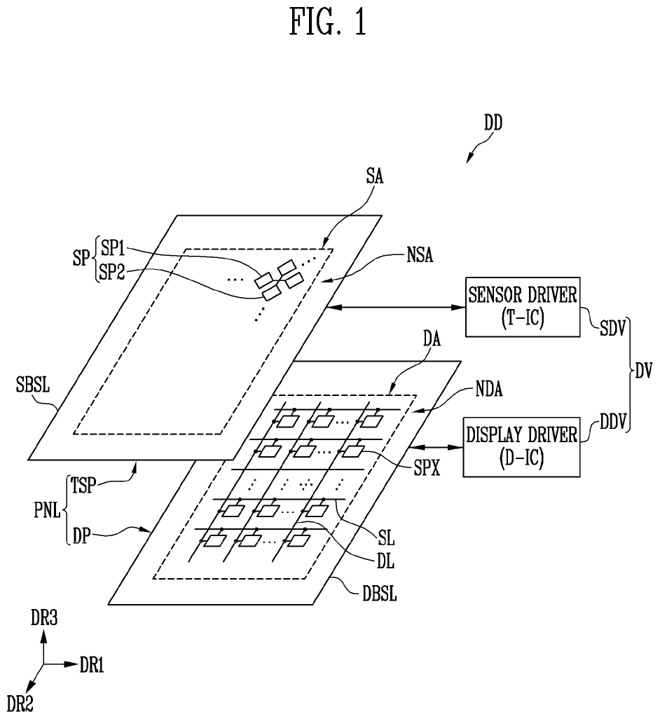

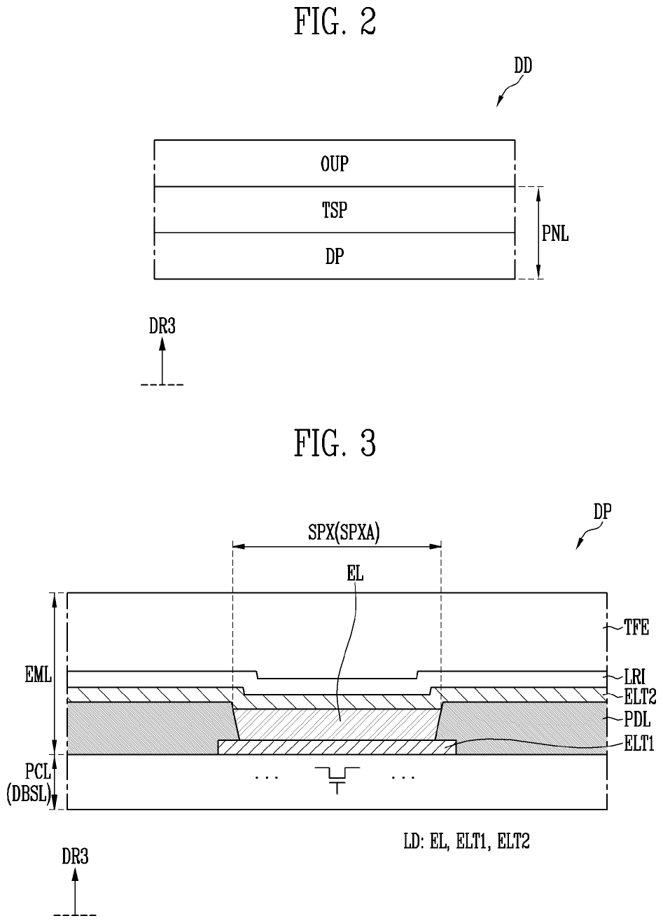

FIG. 1 is a view for describing a display device DD according to some embodiments. FIG. 2 is a schematic sectional view for describing a stacked structure of the display device DD according to some embodiments.

Referring to FIGS. 1 and 2, the display device DD may provide (or emit) light. The display device DD may comprise a panel PNL, and a driving circuit component DV configured to drive the panel PNL. The display device DD may further comprise an outer component OUP.

The panel PNL may comprise a display component DP configured to display images, and a sensor component TSP configured to sense user input (e.g., touch input). The display component DP may be referred to as a display panel. The sensor component TSP may be referred to as a sensing panel.

The panel PNL may comprise sub-pixels SPX and sensing electrodes SP. According to some embodiments, the sub-pixels SPX may display an image during each display frame period. The sensing electrodes SP may sense input (e.g., touch input) from the user during each sensing frame period. The sensing frame period and the display frame period may be independent from each other, or may be different from each other. The sensing frame period and the display frame period may be synchronized with each other, or may not be synchronized.

The sensor component TSP comprising the sensing electrodes SP may obtain information about the touch input from the user. According to some embodiments (e.g., using a mutual capacitance scheme), the sensing electrodes SP may comprise a first sensing electrode SP1 configured to provide a first sensing signal, and a second sensing electrode SP2 configured to provide a second sensing signal. According to some embodiments, the first sensing electrode SP1 may be a transmitter (Tx) pattern electrode, and the second sensing electrode SP2 may be a receiver (Rx) pattern electrode. Information about the touch input (or a touch event) may refer to information comprising a location or the like of a touch provided from the user.

However, embodiments according to the present disclosure are not limited to the foregoing. For example, according to some embodiments (e.g., using a mutual capacitance scheme), the sensing electrodes SP may be configured of one kind of sensing electrodes without being classified into the first sensing electrode SP1 and the second sensing electrode SP2.

The driving circuit component DV may comprise a display driver DDV configured to drive the display component DP, and a sensor driver SDV configured to drive the sensor component TSP.

The display component DP may comprise a display base layer DBSL, and sub-pixels SPX provided on the display base layer DBSL. The sub-pixels SPX may be located in the display area DA.

The display base layer DBSL (or the display device DD) may comprise a display area DA configured to display images, and a non-display area NDA which is an area other than the display area DA. According to some embodiments, the display area DA may be located in a central portion of the display component DP, and the non-display area NDA may be located adjacent to (e.g., in a periphery or outside a footprint of) the display area DA.

The display base layer DBSL may be a base substrate or a base component for supporting the display device DD. The base layer may be a rigid substrate made of glass. Alternatively, the base layer may be a flexible substrate which can be bent, folded, or rolled without damaging the display device DD. In this case, the base layer may comprise insulating material such as polymer resin, e.g., polyimide. However, embodiments according to the present disclosure are not particularly limited to the foregoing.

Scan lines SL, data lines DL, and sub-pixels SPX connected to the scan lines SL and the data lines DL may be located in the display area DA. The sub-pixels SPX may be selected by scan signals each of which has a turn-on level, and which are supplied from the scan lines SL, may be supplied with data signals from the data lines DL, and may emit light having luminance corresponding to the data signals. Consequently, one or more images corresponding to the data signals may be displayed in the display area DA. In the disclosure, the structure of the sub-pixels SPX and the method of driving the sub-pixels SPX are not particularly limited.

Various lines and/or an internal circuit component which are connected to the sub-pixels SPX in the display area DA may be located in the non-display area NDA. For example, a plurality of lines for supplying various power voltages and control signals to the display area DA may be located in the non-display area NDA.

The display component DP may output visible information (e.g., images). According to some embodiments, the type/kind of the display component DP is not particularly limited. For example, the display component DP may be implemented as a self-emissive type display panel such as an organic light emitting display panel. However, in the case in which the display component DP is implemented as a self-emissive type, each pixel is not limited to the case where the pixel comprises only an organic light emitting element. For example, the light emitting element of each pixel may be formed of an organic light emitting diode, an inorganic light emitting diode, a quantum dot/well light emitting diode, or the like. According to some embodiments, the display component DP may be implemented as a non-emission type display panel such as a liquid crystal display panel. In the case in which the display component DP is implemented as a non-emission type, the display device DD may further comprise a light source such as a back-light unit.

Hereinafter, for convenience of explanation, description will be made based on embodiments in which the display component DP is implemented as an organic light emitting display panel.

The sensor component TSP may comprise a sensor base layer SBSL, and a plurality of sensing electrodes SP formed on the sensor base layer SBSL. The sensing electrodes SP may be located in a sensing area SA on the sensor base layer SBSL.

The sensor base layer SBSL (or the display device DD) may comprise the sensing area SA capable of sensing touch input or the like, and a non-sensing area NSA formed around a periphery of the sensing area SA. According to some embodiments, the sensing area SA may be arranged to overlap at least one area of the display area DA. For example, the sensing area SA may be set as an area corresponding to the display area DA (e.g., an area overlapping the display area DA). The non-sensing area NSA may be set as an area corresponding to the non-display area NDA (e.g., an area overlapping the non-display area NDA). In this case, when touch input or the like is provided on the display area DA, the sensor component TSP may detect the touch input.

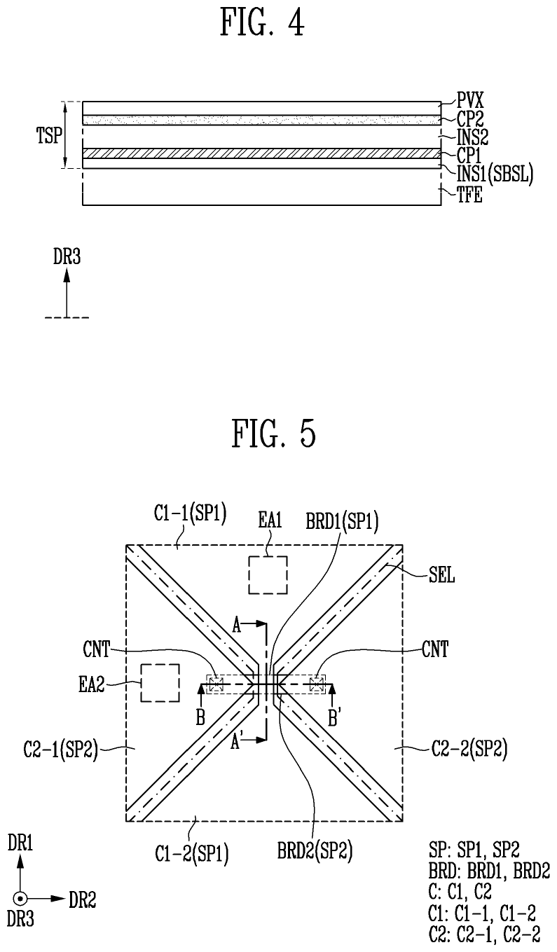

The sensor base layer SBSL may comprise one or more insulating layers (e.g., a first insulating layer INS1 (refer to FIG. 4)). For example, the first insulating layer INS1 provided to form the sensor base layer SBSL may be located on the display component DP, thus forming a base on which the sensing electrodes SP are to be formed. However, an example pertaining to forming the sensor base layer SBSL is not particularly limited.

The sensing area SA may be set as an area (i.e., an active area of the sensor) capable of responding to touch input. To this end, the sensor electrodes SP SC for sensing the touch input or the like may be located in the sensing area SA.

The sensor component TSP may obtain information about input provided from the user. The sensor component TSP may recognize the touch input. The sensor component TSP may use a capacitive sensing scheme to recognize or sense the touch input. The sensor component TSP may sense the touch input in a mutual capacitance scheme, or may sense the touch input in a self-capacitance scheme.

According to some embodiments, each of the first sensing electrodes SP1 may extend in a first direction DR1. The first sensing electrodes SP1 may be arranged in a second direction DR2. The second direction DR2 may differ from the first direction DR1. For example, the second direction DR2 may be a direction perpendicular to the first direction DR1.

According to some embodiments, each of the second sensing electrodes SP2 may extend in the second direction DR2. The second sensing electrodes SP2 may be arranged in the first direction DR1.

According to some embodiments, the first sensing electrodes SP1 and the second sensing electrodes SP2 may have the same shape (e.g., substantially the same shape). For example, the first sensing electrodes SP1, which are Tx pattern electrodes, and the second sensing electrodes SP2, which area Rx pattern electrodes, may have substantially the same shape, so that the performance of sensing a touch event in the sensing area SA can be set to be uniform.

In the non-sensing area NSA of the sensor component TSP, sensing lines may be arranged to electrically connect the sensing electrodes SP with the sensor driver SDV or the like.

The driving circuit component DV may comprise a display driver DDV configured to drive the display component DP, and a sensor driver SDV configured to drive the sensor component TSP.

The display driver DDV may be electrically connected to the display component DP and configured to drive the sub-pixels SPX. The sensor driver SDV may be electrically connected to the sensor component TSP and configured to drive the sensor component TSP.

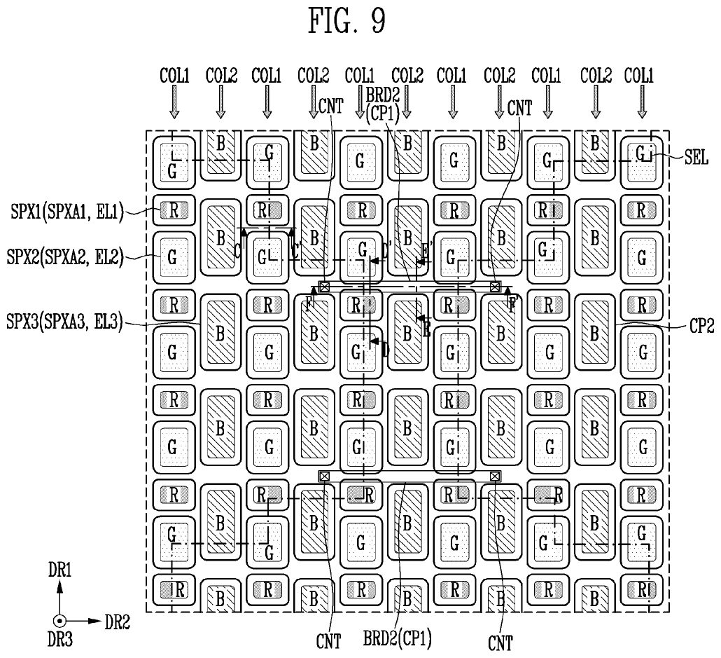

The outer component OUP may be located in substantially the outer portion of the display device DD. The outer component OUP may be located on the sensor component TSP. Light provided from the display device DP may be emitted to the outside through the outer component OUP. According to some embodiments, the outer component OUP may comprise a window. According to some embodiments, the outer component OUP may comprise a reflective control layer RCL (refer to FIG. 9), and a light blocking layer LBL (refer to FIG. 9). According to some embodiments, the outer component OUP may comprise color filters CF1, CF2, and CF3 (refer to FIG. 9).

Next, aspects the display component DP according to some embodiments will be described in more detail with reference to FIG. 3. FIG. 3 is a schematic sectional view illustrating the display component DP according to some embodiments.

Referring to FIG. 3, the display component DP may comprise a pixel circuit layer PCL, and a light-emitting-element layer EML.

The pixel circuit layer PCL may comprise a pixel circuit configured to drive light emitting elements LD. The pixel circuit layer PCL may comprise a display base layer DBSL, conductive layers formed to form pixel circuits, and insulating layers located between the conductive layers.

Each of the pixel circuits may comprise a thin film transistor. The pixel circuit may comprise a driving transistor. The pixel circuit may be electrically connected to the light emitting elements LD, and may provide electrical signals allowing the light emitting elements LD to emit light.

The light-emitting-element layer EML may be located on the pixel circuit layer PCL. According to some embodiments, the light-emitting-element layer EML may comprise a light emitting element LD, a pixel defining layer PDL, a low-reflective inorganic layer LRI, and an encapsulation layer TFE.

The light emitting element LD may be located on the pixel circuit layer PCL. According to some embodiments, the light emitting element LD may comprise a first electrode ELT1, an emission layer EL, and a second electrode ELT2. According to some embodiments, the emission layer EL may be located in an area defined by the pixel defining layer PDL. The pixel defining layer PDL may be adjacent to a periphery of the emission layer EL. One surface of the emission layer EL may be electrically connected to the first electrode ELT1. The other surface of the emission layer EL may be electrically connected to the second electrode ELT2.

The first electrode ELT1 may be an anode electrode for the emission layer EL. The second electrode ELT2 may be a common electrode (or a cathode electrode) for the emission layer EL. According to some embodiments, the first electrode ELT1 and the second electrode ELT2 may comprise conductive material. For example, the first electrode ELT1 may comprise conductive material having reflectibility (e.g., conductive material that has light-reflecting properties). The second electrode ELT2 may comprise transparent conductive material. However, embodiments according to the present disclosure are not limited thereto.

The emission layer EL may have a multilayer thin-film structure comprising a light generation layer. The emission layer EL may comprise: a hole injection layer into which holes are injected; a hole transport layer which has excellent hole transportation performance and restrains movement of electrons that have not been coupled with holes in the light generation layer and thus increases chances of recombination between holes and electrons; the light generation layer which emits light by recombination between injected electrons and holes; a hole blocking layer which restrains movement of holes that have not been coupled with electrons in the light generation layer; an electron transport layer which is provided to smoothly transport electrons to the light generation layer; and an electron injection layer into which electrons are injected. The emission layer EL may emit light based on an electrical signal which is provided from the first electrode ELT1 and the second electrode ELT2.

The emission layer EL may form a sub-pixel SPX. The emission layer EL may form a sub-pixel area SPXA configured to emit a color of light. In a plan view (e.g., a view perpendicular or normal with respect to the display surface of the display device DD or a plane defined by the first direction DR1 and the second direction DR2), an area of the emission layer EL and the sub-pixel area SPXA may correspond to each other. For example, each emission layer EL may correspond to an associated sub-pixel area SPXA.

The pixel defining layer PDL may be located on the pixel circuit layer PCL, and may define a position at which the emission layer EL is to be located. The pixel defining layer PDL may comprise organic material. According to some embodiments, the pixel defining layer PDL may be formed of one or more selected from the group consisting of acryl resin, epoxy resin, phenol resin, polyamide resin, and polyimide resin. However, embodiments according to the present disclosure are not limited thereto.

The low-reflective inorganic layer LRI may be located on the light emitting element LD (e.g., the second electrode ELT2). The low-reflective inorganic layer LRI may be located between the encapsulation layer TFE and the light emitting element LD.

The low-reflective inorganic layer LRI may comprise inorganic material. For example, the low-reflective inorganic layer LRI may comprise one or more among metal or a metallic compound, taking into account a refractive index and an absorption coefficient. The low-reflective inorganic layer LRI may absorb light applied into the display device DD from the outside, and may reduce an external light reflectivity of the display device DD. As such, because the low-reflective inorganic layer LRI is comprised, the display quality and visibility of the display device DD can be enhanced.

The encapsulation layer TFE may be located on the low-reflective inorganic layer LRI. The encapsulation layer TFE may offset a step difference formed by the light emitting element LD, the low-reflective inorganic layer LRI, and the pixel defining layer PDL. The encapsulation layer TFE may comprise a plurality of insulating layers configured to cover the light emitting element LD. According to some embodiments, the encapsulation layer TFE may have a structure formed by alternately stacking inorganic layers and organic layers. According to some embodiments, the encapsulation layer TFE may be a thin film encapsulation layer.

Next, aspects of the sensor component TSP according to some embodiments will be described in more detail with reference to FIGS. 4 to 7.

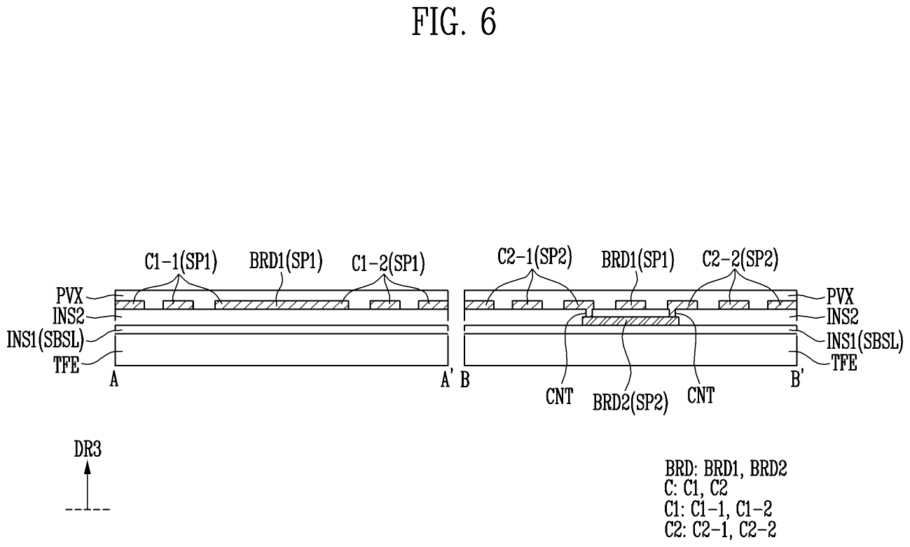

FIG. 4 is a schematic sectional view illustrating a sensing component according to some embodiments. FIG. 5 is a schematic plan view illustrating sensing electrodes according to some embodiments. FIG. 5 illustrates a schematic planar structure showing an area where a first sensing electrode SP1 and a second sensing electrode SP2 are adjacent to each other. FIG. 6 is a schematic sectional view illustrating the sensing according to some embodiments. FIG. 6 illustrates a schematic sectional structure taken along line A-A′ of FIG. 5, and a sectional structure taken along line B-B′ of FIG. 5

Referring to FIGS. 4 to 6, the sensor component TSP may be located on the encapsulation layer TFE. The sensor component TSP may comprise a first insulating layer INS1, a first conductive pattern CP1, a second insulating layer INS2, a second conductive pattern CP2, and a passivation layer PVX.

According to some embodiments, the first conductive pattern CP1 and the second conductive pattern CP2 may be patterned in one area to form sensing electrodes SP. For example, a portion of each of the first conductive pattern CP1 and the second conductive pattern CP2 may form a first sensing electrode SP1. A portion of each of the first conductive pattern CP1 and the second conductive pattern CP2 may form a second sensing electrode SP2. However, embodiments according to the present disclosure are not limited thereto.

The first insulating layer INS1 may be located on the encapsulation layer TFE. The first insulating layer INS1 may form a sensor base layer SBSL and thus provide an area in which the first conductive pattern CP1, the second insulating layer INS2, the second conductive pattern CP2, and the passivation layer PVX are located.

The first conductive pattern CP1 may be located on the first insulating layer INS1. The second conductive pattern CP2 may be located on the second insulating layer INS2. The first conductive pattern CP1 and the second conductive pattern CP2 may be spaced apart from each other with the second insulating layer INS2 interposed therebetween.

The first conductive pattern CP1 and the second conductive pattern CP2 each may comprise a single metallic layer or multiple metallic layers. The first conductive pattern CP1 and the second conductive pattern CP2 may comprise at least one of various metals comprising gold (Au), silver (Ag), aluminum (Al), molybdenum (Mo), chrome (Cr), titanium (Ti), nickel (Ni), neodymium (Nd), copper (Cu), platinum (Pt), and the like, or an alloy thereof. According to some embodiments, the first conductive pattern CP1 and the second conductive pattern CP2 may comprise at least one of various transparent conductive materials comprising at least one among a silver nanowire (AgNW), indium tin oxide (ITO), indium zinc oxide (IZO), indium gallium zinc oxide (IGZO), antimony zinc oxide (AZO), indium tin zinc oxide (ITZO), zinc oxide (ZnO), tin oxide (SnO₂), carbon nanotubes, or graphene.

The second insulating layer INS2 may be located on the first conductive pattern CP1. The second insulating layer INS2 may be interposed between the first conductive pattern CP1 and the second conductive pattern CP2. The passivation layer PVX may be located on the second conductive pattern CP2.

The first insulating layer INS1 may comprise one or more of inorganic material and organic material. The second insulating layer INS2 may comprise one or more of inorganic material and organic material. According to some embodiments, the passivation layer PVX may comprise organic material. The inorganic material may comprise one or more selected from the group consisting of silicon nitride (SiNₓ), silicon oxide (SiOₓ), silicon oxynitride (SiOₓN_{y}), and aluminum oxide (AlOₓ). The organic material may comprise one or more selected from the group consisting of acryl resin, epoxy resin, phenol resin, polyamide resin, and polyimide resin. However, the disclosure is not limited thereto.

The sensing electrodes SP may comprise a cell C and a bridge BRD. The cell C may have a relatively large surface area. The bridge BRD may have a relatively small surface area. Cells C adjacent to each other may be electrically connected to each other by the bridge BRD. The cell C may comprise a first cell C1 and a second cell C2. The bridge BRD may comprise a first bridge BRD1 and a second bridge BRD2.

According to some embodiments, the first cell C1 and the second cell C2 may be formed by the second conductive pattern CP2. The first bridge BRD1 may be formed by the second conductive pattern CP2. The second bridge BRD2 may be formed by the first conductive pattern CP1.

According to some embodiments, the cells C may form a mesh structure. For example, the second conductive pattern CP 2 for forming the cells C may be patterned according to the mesh structure. Because the cells C form a mesh structure, capacitance which may be formed between the cells C and other electrodes located thereunder may be reduced.

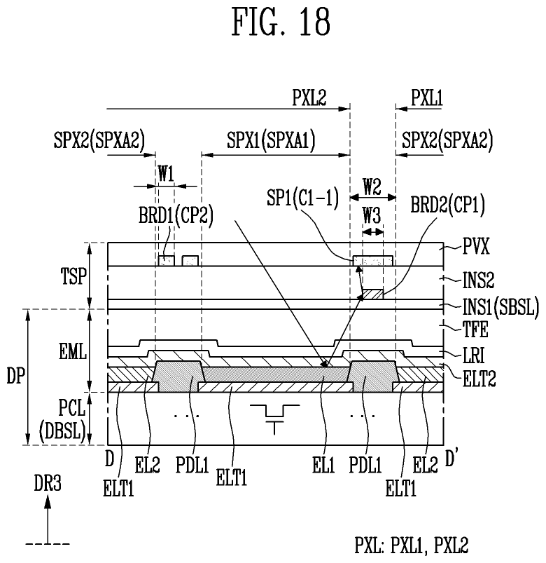

According to some embodiments, a first width W1 (refer to FIG. 18) of the second conductive pattern CP2 that does not overlap the first conductive pattern CP1 may be less than a width (e.g., a second width W2 (refer to FIG. 18)) of the second conductive pattern CP2 that overlaps the first conductive pattern CP1. For example, the second conductive pattern CP2 that forms the cells C may have the first width W1. The first width W1 may be greater than the width of the second conductive pattern CP2 that is arranged around an area in which the second bridge BRD2 is located. Further detailed description pertaining to the foregoing will be made below.

The first sensing electrode SP1 may have a structure in which the first cells C1 each having a relatively large surface area and the first bridge BRD1 having a relatively small surface area are connected to each other. For example, the first cell C1 may comprise a 1-1-th cell C1-1 and a 1-2-th cell C1-2. The first bridge BRD1 may electrically connect the 1-1-th cell C1-1 and the 1-2-th cell C1-2 to each other.

The second sensing electrode SP2 may have a structure in which the second cells C2 each having a relatively large surface area and the second bridge BRD2 having a relatively small surface area are connected to each other. For example, the second cell C2 may comprise a 2-1-th cell C2-1 and a 2-2-th cell C2-2. The second bridge BRD2 may electrically connect the 2-1-th cell C2-1 and the 2-2-th cell C2-2 to each other.

According to some embodiments, the second bridge BRD2 may be electrically connected to the 2-1-th cell C2-1 through a contactor CNT, and may be electrically connected to the 2-2-th cell C2-2 through another contactor CNT. Hence, the second bridge BRD2 that is located on a layer different from that of the second cell C2 may electrically connect the 2-1-th cell C2-1 and the 2-2-th cell C2-2 to each other through the contactor CNT. According to some embodiments, the contactor CNT may pass through the second insulating layer INS2.

The first cell C1 and the second cell C2 each may have a diamond shape. However, the shape of each of the first cell C1 and the second cell C2 is not particularly limited to the foregoing.

The first sensing electrodes SP1 and the second sensing electrodes SP2 may be adjacent to each other with a separation line SEL interposed therebetween. The separation line SEL may be an imaginary line located in an area between the first sensing electrodes SP1 and the second sensing electrodes SP2. For example, the separation line SEL may be located between the 1-1-th cell C1-1 and the 1-2-th cell C1-2. The separation line SEL may be located between the first bridge BRD1 and the 1-2-th cell C1-2.

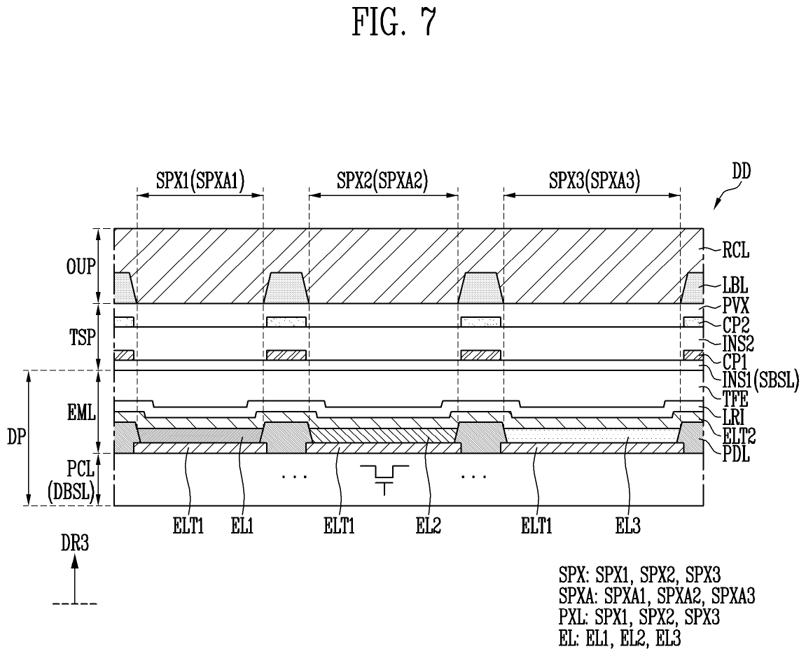

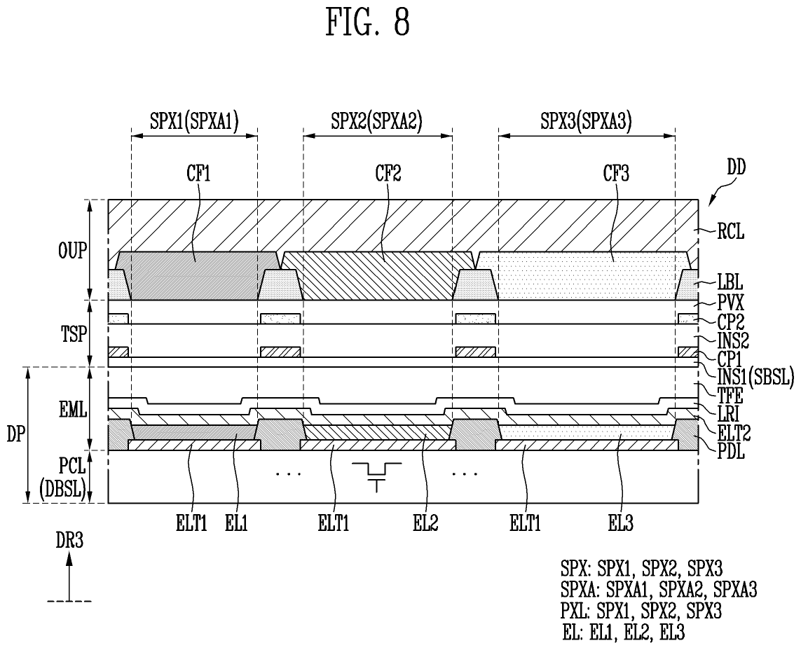

Next, a cross-sectional structure of the display device DD according to some embodiments will be described with reference to FIGS. 7 and 8. FIGS. 7 and 8 are schematic sectional views each illustrating a display device according to some embodiments.

Referring to FIG. 7, the emission layer EL may comprise a first emission layer EL1 comprised in the first sub-pixel SPX1, a second emission layer EL2 comprised in the second sub=pixel SPX2, and a third emission layer EL3 comprised in the third sub-pixel SPX3. The first emission layer EL1 may emit a first color of light (e.g., red light), and may form a first sub-pixel area SPXA1. The second emission layer EL2 may emit a second color of light (e.g., green light), and may form a second sub-pixel area SPXA2. The third emission layer EL3 may emit a third color of light (e.g., blue light), and may form a third sub-pixel area SPXA3.

In the sensor component TSP, the first conductive pattern CP1 and the second conductive pattern CP2 may be located on different layers, thus forming the structure of the sensing electrodes SP.

The outer component OUP may be located on the sensor component TSP. The outer component OUP may comprise the light blocking layer and the reflective control layer RCL.

The light blocking layer LBL may overlap the first conductive pattern CP1 and the second conductive pattern CP2, in a plan view. The light blocking layer LBL may comprise light blocking material, but embodiments according to the present disclosure are not limited thereto.

The reflective control layer RCL may selectively absorb light in one wavelength range, and control the reflectivity and the color sense. According to some embodiments, the reflective control layer RCL may comprise a dye, a pigment, or a combination thereof. For example, the reflective control layer RCL may comprise one or more selected from the group consisting of an oxazine-based compound, a cyanine-based compound, a tetraazaporphyrin-based compound, and a squarylium-based compound, but embodiments according to the present disclosure are not limited thereto.

According to some embodiments, the sub-pixel areas SPXA may be different from each other in size (or surface area). The respective surface areas of the first sub-pixel area SPXA1, the second sub-pixel area SPXA2, and the third sub-pixel area SPXA3 may be different from each other. For example, the surface area of the third sub-pixel area SPXA3 may be greater than the surface area of the second sub-pixel area SPXA2. The surface area of the second sub-pixel area SPXA2 may be greater than the surface area of the first sub-pixel area SPXA1. However, embodiments according to the present disclosure are not limited thereto. According to some embodiments, the surface area of the second sub-pixel area SPXA2 may be the same as the surface area of the first sub-pixel area SPXA1. Hereinafter, for convenience of explanation, description will be made based on embodiments in which the surface area of the second sub-pixel area SPXA2 is greater than the surface area of the first sub-pixel area SPXA1.

According to some embodiments, the surface areas of some sub-pixel areas SPXA may be formed to be different from that of the other sub-pixel areas SPXA, so that an emission efficiency deviation between the sub-pixels SPX by colors can be compensated for.

According to some embodiments, referring to FIG. 8, the outer component OUP may further comprise color filters CF1, CF2, and CF3. According to some embodiments, because the color filters CF1, CF2, and CF3 corresponding to the respective colors of the first to third sub-pixels SPXL1, SPXL2, and SPXL3 are located, a full-color image may be displayed.

The first color filter CF1 may be a color filter provided to form the first sub-pixel SPX1, and may overlap the first sub-pixel area SPXA1, in a plan view. The first color filter CF1 allows a first color of light to selectively pass therethrough. The first color filter CF1 may be a red color filter, and may comprise red color filter material.

The second color filter CF2 may be a color filter provided to form the second sub-pixel SPX2, and may overlap the second sub-pixel area SPXA2, in a plan view. The second color filter CF2 allows a second color of light to selectively pass therethrough. The second color filter CF2 may be a green color filter, and may comprise green color filter material.

The third color filter CF3 may be a color filter provided to form the third sub-pixel SPX3, and may overlap the third sub-pixel area SPXA3, in a plan view. The third color filter CF3 allows a third color of light to selectively pass therethrough. The third color filter CF3 may be a blue color filter, and may comprise blue color filter material.

The cross-sectional structure of the display device DD according to some embodiments is not limited to the foregoing example.

Hereinafter, the structures of the first conductive pattern CP1, the second conductive pattern CP2, and the sub-pixels SPX of the display device DD will be described with reference to FIGS. 9 to 38. Description overlapping that of the embodiments described above will be simplified, or may not be repeated.

First, a display device DD according to some embodiments will be described with reference to FIGS. 9 to 20. FIGS. 9 to 20 are schematic views each illustrating the display device DD according to some embodiments.

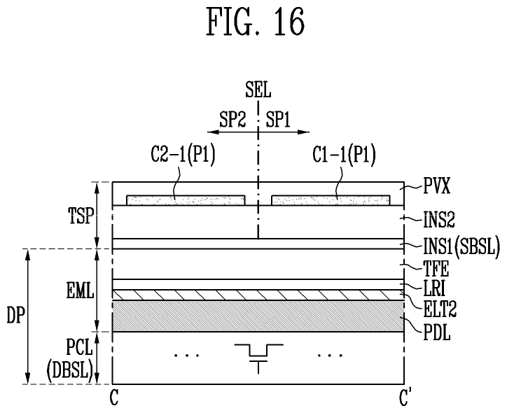

FIGS. 9 to 15 are schematic plan views each illustrating the display device DD according to some embodiments. FIGS. 16 to 20 are schematic sectional views each illustrating the display device DD according to some embodiments.

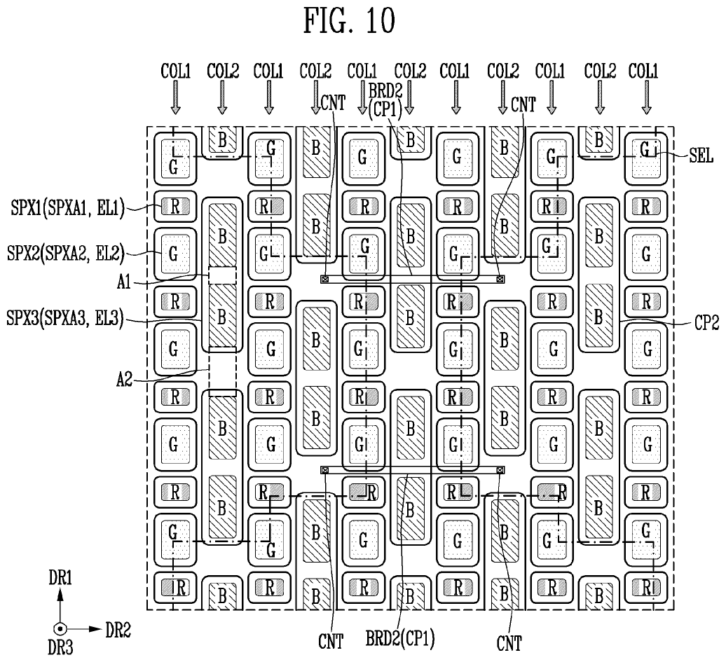

FIGS. 9, 10, and 12 are schematic plan views illustrating sub-pixel areas, the first conductive pattern CP1, and the second conductive pattern CP2. FIGS. 9, 10, and 12 illustrate sub-pixels SPX1, SPX2, and SPX3 (or emission layers EL1, EL2, and EL3) which form the sub-pixel areas SPXA1, SPXA2, and SPXA3, and illustrate conductive patterns CP1 and CP2 formed around the sub-pixel areas SPXA. In FIGS. 9 and 10, a portion of the second conductive pattern CP2 is indicated by a thick solid line for convenience of explanation.

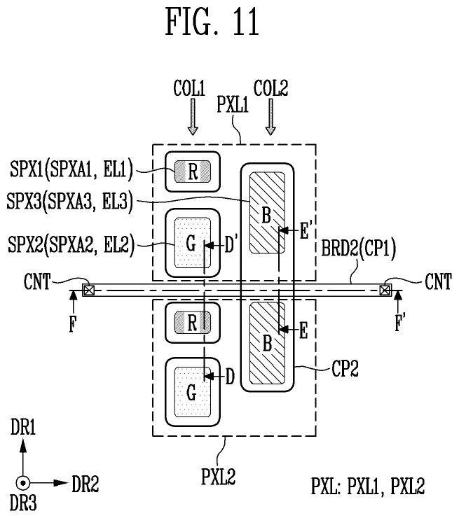

FIG. 11 schematically illustrates adjacent pixels PXL1 and PXL2 based on an area in which the second bridge BRD2 is located.

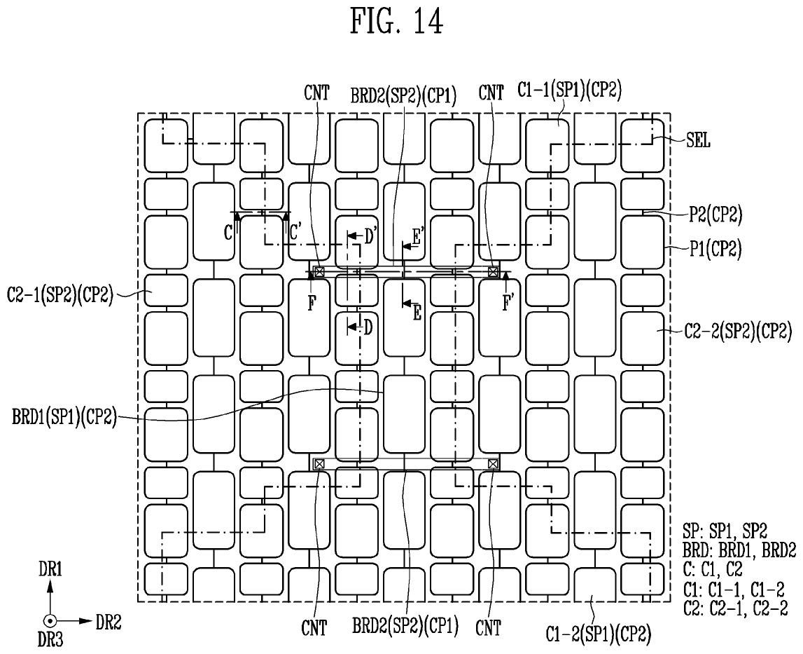

FIG. 14 illustrates the first conductive pattern CP1 and the second conductive pattern CP2, and does not illustrate the sub-pixels SPX1, SPX2, and the SPX3 to enable the first conductive pattern CP1 and the second conductive pattern CP2 to be more clearly understood. FIG. 14 illustrates the same area as that of FIG. 9, so that a position relationship between the first conductive pattern CP1, the second conductive pattern CP2, and the sub-pixels SPX1, SPX2, and SPX3 may be clearly understood.

Referring to FIGS. 9 to 11, each of the sub-pixels SPX according to some embodiments may be arranged according to one structure. For example, the sub-pixels SPX may be arranged according to an S-stripe structure. In the following description, a position relationship of the sub-pixels SPX1, SPX2, and SPX3 may correspond to a position relationship of the sub-pixel areas SPXA1, SPXA2, and SPXA3 and/or the emission layers EL1, EL2, and EL3.

The first sub-pixel SPX1 and the second sub-pixel SPX2 may form a first pixel column COL1. The first sub-pixel SPX1 and the second sub-pixel SPX2 may be successively arranged in the first direction DR1. First sub-pixels SPX1 and second sub-pixels SPX2 may be alternately arranged in the first direction DR1. The first sub-pixel SPX1 and the second sub-pixel SPX2 may be located in the first pixel column COL1 without the third sub-pixel SPX3 located therein.

The third sub-pixel SPX3 may form a second pixel column COL2. Third sub-pixels SPX3 may be successively arranged in the first direction DR1. The third sub-pixel SPX3 may be located in the second pixel column COL2 without the first sub-pixel SPX1 and the second sub-pixel SPX2 located therein.

According to some embodiments, the third sub-pixels SPX3 may be spaced apart from each other at regular intervals in the first direction DR1 (refer to FIG. 9). However, the disclosure is not limited thereto. According to some embodiments, third sub-pixels SPX3 may be spaced apart from each other by a first distance in a first area A1. Other third sub-pixels SPX3 may be spaced apart from each other by a second distance greater than the first distance in a second area A2 adjacent to the first area A1 in the third direction DR1.

The first pixel column COL1 and the second pixel column COL2 may be adjacent to each other in the second direction DR2. For example, the first sub-pixel SPX1 may be adjacent to the third sub-pixel SPX3 in the second direction DR2. The second sub-pixel SPX2 may be adjacent to the third sub-pixel SPX3 in the second direction DR2.

First pixel columns COL1 and second pixel columns COL2 may be alternately arranged in the second direction DR2. For example, each second pixel column COL2 may be located between two first pixel columns COL1. Each first pixel column COL1 may be located between two second pixel columns COL2.

The first sub-pixel SPX1 and the second sub-pixel SPX2 that are adjacent to each other in the first direction DR1 and the third sub-pixel SPX3 that is adjacent to the first and second sub-pixels SPX1 and SPX2 in the second direction DR2 may form a pixel PXL (or a pixel unit). For example, the first to third sub-pixels SPX1, SPX2, and SPX3 may form a first pixel PXL1. The first to third sub-pixels SPX1, SPX2, and SPX3 that are in an area adjacent to the first pixel PXL1 in the first direction DR1 may form a second pixel PXL2. The pixels PXL may be successively arranged along the first direction DR1 and the second direction DR2.

Referring to FIGS. 9, 10, and 14, the first sensing electrode SP1 and the second sensing electrode SP2 are located. For example, the first cell C1 and the second cell C2 may be spaced apart from each other based on the separation line SEL. The second cell C2 and the first bridge BRD1 may be spaced apart from each other based on the separation line SEL.

The second conductive pattern CP2 may be arranged around the sub-pixel SPX (or the sub-pixel areas SPXA). The second conductive pattern CP2 may enclose at least some of the sub-pixel areas SPXA, in a plan view. The second conductive pattern CP2 may be located in a peripheral portion of the sub-pixel SPX, so that the emission efficiency may be prevented from being reduced, and deterioration in external visibility may be minimized. The light blocking layer LBL and the pixel defining layer PDL may be located in the peripheral portion of the sub-pixel SPX. For example, the second conductive pattern CP2 may be arranged to overlap the light blocking layer LBL and the pixel defining layer PDL.

According to some embodiments, the second conductive pattern CP2 may comprise a first portion P1 and a second portion P2. The first portion P1 may form a loop (e.g., a closed loop or an open loop) enclosing one or more of the sub-pixel areas SPXA. The second portion P2 may connect first portions P1 to each other. Therefore, in a plan view, two or more first portions P1 may be connected to each other by the second portion P2 so that the cells C may have a mesh structure. According to some embodiments, the first portion P1 and the second portion P2 may form the cell C, or may form the bridge BRD.

According to some embodiments, the first portion P1 may have a size and a shape corresponding to corresponding sub-pixels SPX. For example, the first portion P1 may comprise a 1-1-th portion P1-1, a 1-2-th portion P1-2, and a 1-3-th portion P1-3. The 1-1-th portion P1-1 may enclose at least a portion of the first sub-pixel area SPXA1. The 1-2-th portion P1-2 may enclose at least a portion of the second sub-pixel area SPXA2. The 1-3-th portion P1-3 may enclose at least a portion of the third sub-pixel area SPXA3. According to some embodiments, the 1-3-th portion P1-3 may be greater than the 1-1-th portion P1-1 or the 1-2-th portion P1-2.

According to some embodiments, the first portion P1 and the second portion P2 may be disconnected on the separation line SEL. The foregoing will be described with reference to FIG. 16. FIG. 16 is a schematic sectional view taken along line C-C′ of FIGS. 9 and 14.

Referring to FIG. 16, the first sensing electrode SP1 and the second sensing electrode SP2 may be spaced apart from each other, with the separation line SEL interposed therebetween. For example, the first portion P1 that forms the 2-1-th cell C2-1 and the first portion P1 that forms the 1-1-th cell C1-1 may be spaced apart from each other, with the separation line SEL interposed therebetween. For convenience of explanation, the disconnected structure of the first portion P1 and the second portion P2 is not illustrated in FIGS. 9, 10, and 14.

Because the second conductive patterns CP2 are electrically separated from each other with the separation line SEL interposed therebetween, the first sensing electrode SP1 and the second sensing electrode SP2 to which different sensing signals can be supplied may be defined.

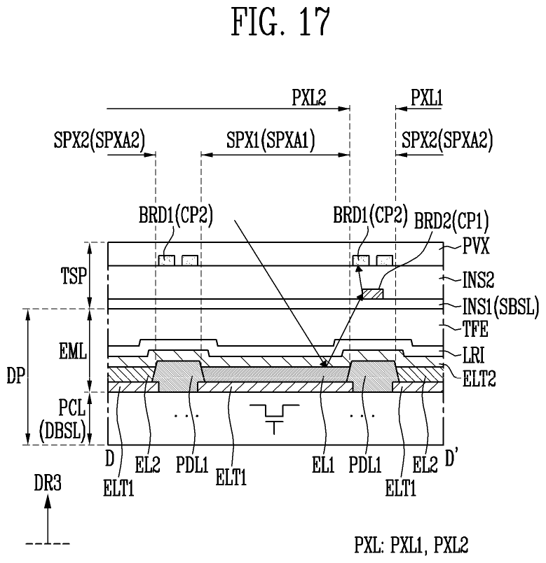

According to some embodiments, the first conductive pattern CP1 may form the second bridge BRD2. Technical characteristics of the second bridge BRD2 will be described with reference to FIGS. 17 to 20.

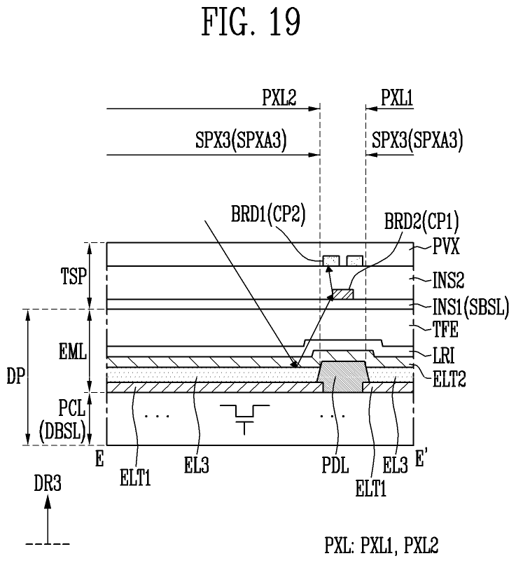

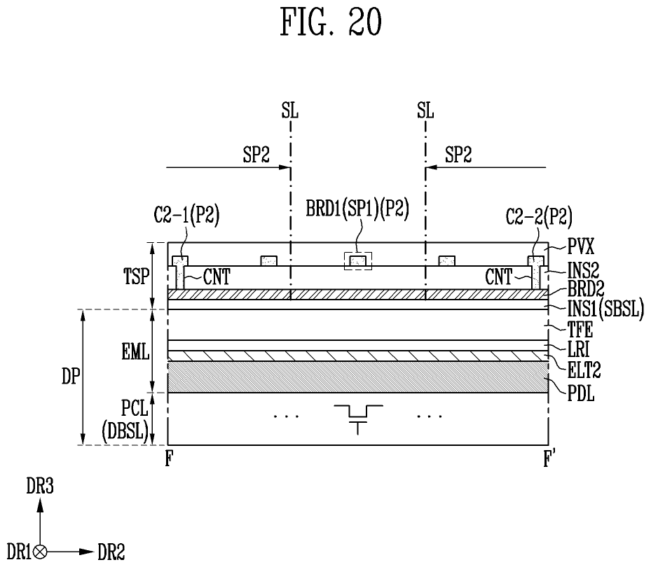

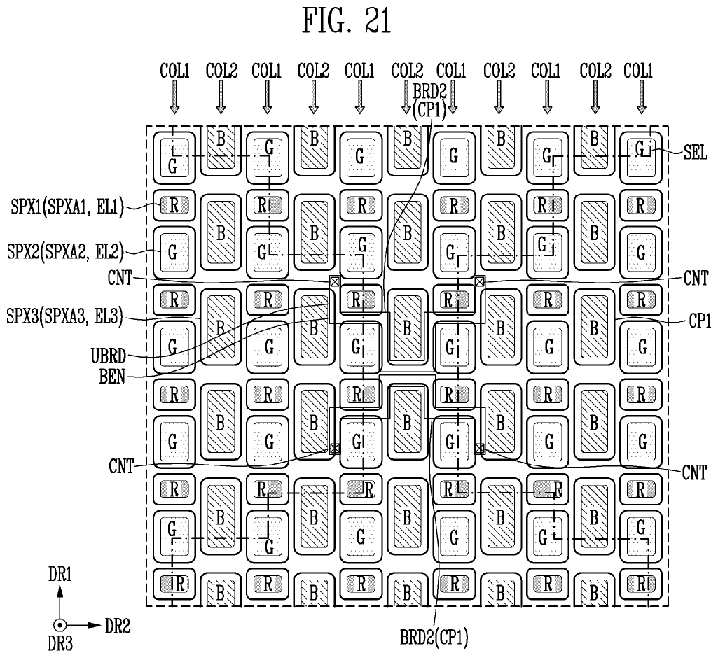

FIGS. 17 and 18 are schematic sectional view taken along line D-D′ of FIGS. 9, 11, and 14. FIG. 19 is a schematic sectional view taken along line E-E′ of FIGS. 9, 11, and 14. FIG. 20 is a schematic sectional view taken along line F-F′ of FIGS. 9, 11, and 14.

The second bridge BRD2 may be located in a layer provided under the second conductive pattern CP2, and may electrically connect the 2-1-th cell C2-1 and the 2-2-th cell C2-2 to each other. For example, the second bridge BRD2 may be electrically connected, through a contactor CNT, to the first portion P1 or the second portion P2 that forms the 2-1-th cell C2-1. The second bridge BRD2 may be electrically connected, through a contactor CNT, to the first portion P1 or the second portion P2 that forms the 2-2-th cell C2-2.

The second bridge BRD2 may extend in a direction in which the 2-1-th cell C2-1 and the 2-2-th cell C2-2 are spaced apart from each other. For example, at least a portion of the second bridge BRD2 may extend in the second direction DR2. According to some embodiments, the second bridge BRD2 may generally extend in the second direction DR2. According to some embodiments, a portion of the second bridge BRD2 may extend in the second direction DR2. Another portion of the second bridge BRD2 may extend in a direction different from the second direction DR2 (in a diagonal direction extending between the first direction DR1 and the second direction DR2). However, the shape of the second bridge BRD2 is not limited to a specific example.

According to some embodiments, the second bridge BRD2 may comprises two or more second bridges BRD2, so that the 2-1-th cell C2-1 and the 2-2-th cell C2-2 may be electrically connected to each other at two or more positions. However, the disclosure is not limited to the foregoing.

The second bridge BRD2 may pass between the first sub-pixel SPX1 and the second sub-pixel SPX2. For example, at least a portion of the second bridge BRD2 may be located between the first sub-pixel SPX1 and the second sub-pixel SPX2. According to some embodiments, at least a portion of the second bridge BRD2 may be located between the second sub-pixel SPX2 of the first pixel PXL1 and the first sub-pixel SPX1 of the second pixel PXL2. According to some embodiments, at least a portion of the second bridge BRD2 may be located between the first sub-pixel SPX1 of the first pixel PXL1 and the second sub-pixel SPX2 of the second pixel PXL2.

The second bridge BRD2 may pass between the third sub-pixels SPX3 adjacent to each other. For example, at least another portion of the second bridge BRD2 may be located between the third sub-pixels SPX3 adjacent to each other. According to some embodiments, the at least another portion of the second bridge BRD2 may be located between the third sub-pixel SPX3 of the first pixel PXL1 and the third sub-pixel SPX3 of the second pixel PXL2.

According to some embodiments, the second bridge BRD2 may have a structure extending substantially in one direction (e.g., the second direction DR2), in a plan view. According to some embodiments, the second bridge BRD2 may have a linear structure extending in the second direction DR2 rather than having a mesh structure. According to some embodiments, the second bridge BRD2 may have a structure extending in one direction without comprising a bent area, in a plan view. In this case, the second bridge BRD2 may connect the contactor CNT for the 2-1-th cell C2-1 and the contactor CNT for the 2-2-th cell C2-2 to each other by the shortest distance.

In this case, a range of a multilayer area in which the first conductive pattern CP1 and the second conductive pattern CP2 overlap each other may be minimized. Experimentally, in the case where the multilayer area is formed, there is the possibility of deterioration in visibility because the reflectivity of external light in the multilayer area is different from the reflectivity of external light in an area other than the multilayer area. However, according to some embodiments, thanks to the shape and arrangement structure of the second bridge BRD2, the formation of the multilayer area may be relatively minimized or reduced, so that the visibility of the display device DD can be enhanced.

Consequently, the structure of the second bridge BRD2 may be a structure capable of reducing the range of the multilayer area to optimize the reflection of external light in the arrangement structure of the sub-pixels SPX1, SPX2, and SPX3 according to some embodiments.

According to some embodiments, the second bridge BRD2 may be arranged to overlap the second portion P2. According to some embodiments, the second portion P2 may be a bridge electrode provided to electrically connect the first portions P1 corresponding to the shape of the sub-pixel SPX, and may be patterned with a relatively small surface area compared to that of the first portion P1. Hence, the second bridge BRD2 may be selectively located at a position overlapping the second portion P2, with a minimized overlapping area with the first portion P1. In this case, in a manner similar to the foregoing case, formation of the multilayer area may be reduced, so that the visibility of the display device DD can be enhanced.

According to some embodiments, the contactor CNT may overlap the third sub-pixels SPX3 in the first direction DR1. The contactor CNT may be located in the second pixel column COL2. According to some embodiments, the contactor CNT formed on one end of the second bridge BRD2 may be located in one second pixel column COL2. The contactor CNT formed on the other end of the second bridge BRD2 may be located in another second pixel column COL2.

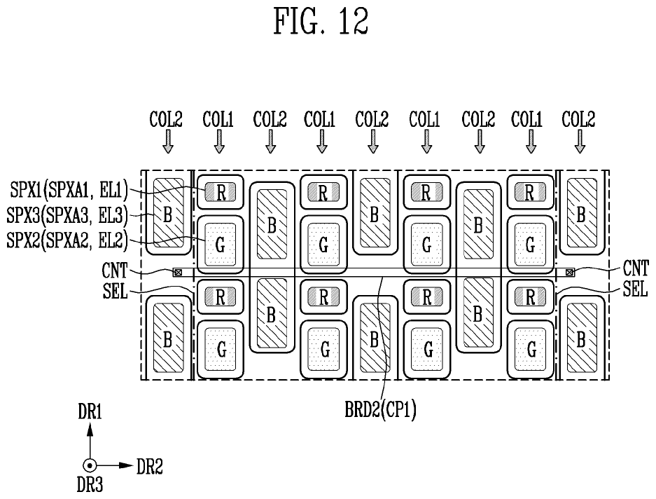

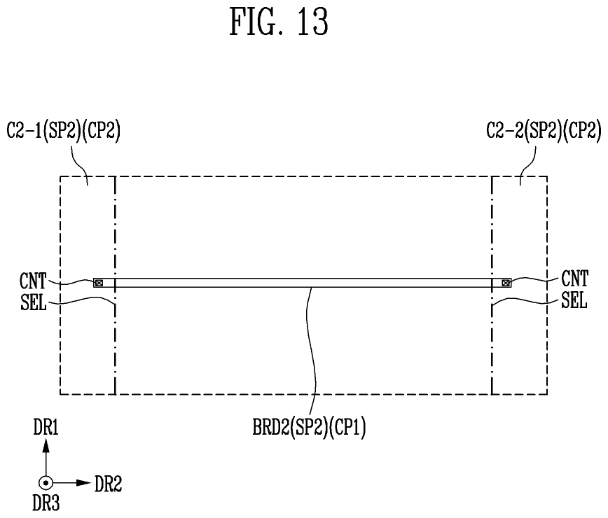

According to some embodiments, the numbers of first pixel columns COL1 and second pixel columns COL2 that overlap the second bridge BRD2 are not particularly limited. For example (referring to FIGS. 9 and 10), the second bridge BRD2 may overlap the second pixel column COL2 in the first direction DR1 and also overlap both the first pixel column COL1 that is located on one side of the overlapping second pixel column COL2 and the first pixel column COL1 that is located on the other side of the overlapping second pixel column COL2. Alternatively, in another example (referring to FIGS. 12 and 13), at least a portion of the second bridge BRD2 may extend in the second direction DR1, and overlap three first pixel columns COL1 and three second pixel columns COL2 in the first direction DR1. For reference, FIGS. 12 and 13 illustrate one or more components located in the same area in the sensing area SA. Referring to FIGS. 12 and 13, the position relationship between the sensing electrodes SP and the sub-pixel areas SPXA may be clearly understood.

According to some embodiments, in the case where the third sub-pixels SPX3 are irregularly arranged in the first direction DR1 (refer to FIG. 10), the second bridge BRD2 may pass between the third sub-pixels SPX3 that are spaced apart from each other by a relatively small distance. In this case, the contactor CNT of the second bridge BRD2 may be formed in an area (e.g., the second area A2) between the third sub-pixels SPX3 that are spaced apart from each other by a relatively large distance. In this case, because the contactor CNT may be spaced apart from the sub-pixels SPX by a sufficiently large distance, the processing convenience may be enhanced. Embodiments according to the present disclosure are not limited thereto. According to some embodiments, the contactor CNT may be formed in an area other than the area (e.g., the second area A2) between the third sub-pixels SPX3.

According to some embodiments, an end of the first conductive pattern CP1 may be entirely covered with the second conductive pattern CP2, in a plan view. For example, one end of the first conductive pattern CP1 may be covered with one of the first bridges BRD1, and the other end of the first conductive pattern CP1 may be covered with another one of the second bridges BRD2. For example, an end of the second bridge BRD2 may be entirely covered with the first bridge BRD1. According to some embodiments, the end of the second bridge BRD2 may be entirely covered with the cell C. Hence, a side surface of the first conductive pattern CP1 may entirely overlap the second conductive pattern CP2, in a plan view.

According to some embodiments, some of the second conductive patterns CP2 that overlap the first conductive pattern CP1 may be patterned to have a relatively large width. In this case, the second conductive pattern CP2 may cover the side surface of the first conductive pattern CP1, in a plan view. For example, as described above, the second conductive pattern CP2 (e.g., the cell C and the first bridge BRD1) that does not overlap the first conductive pattern CP1 may have a first width W1. The second conductive pattern CP2 that overlaps the first conductive pattern CP2 may have a second width W2. According to some embodiments, the first conductive pattern CP1 may have a third width W3. According to some embodiments, the second width W2 may be greater than the first width W1. The second width W2 may be greater than the third width W3. In this case, the second conductive pattern CP2 that is adjacent to the first conductive pattern CP1 may cover the side surface of the first conductive pattern CP1.

According to the above-mentioned structure, a risk of reflection of external light applied into the display device DD may be reduced. According to some embodiments, FIGS. 17 to 19 each illustrate a light path of external light which is applied into the display device DD and blocked by the second conductive pattern CP2. Experimentally, in the case where external light is applied into the display device DD, the external light may be reflected by the side surface of the first conductive pattern CP1 and emitted to the outside, so that there is the possibility of deterioration in visibility of the display device DD. However, the side surface of the first conductive pattern CP1 according to some embodiments may be entirely covered with the second conductive pattern CP2, so that external light can be prevented from being reflected by the first conductive pattern CP1, whereby the visibility of the display device DD can be enhanced.

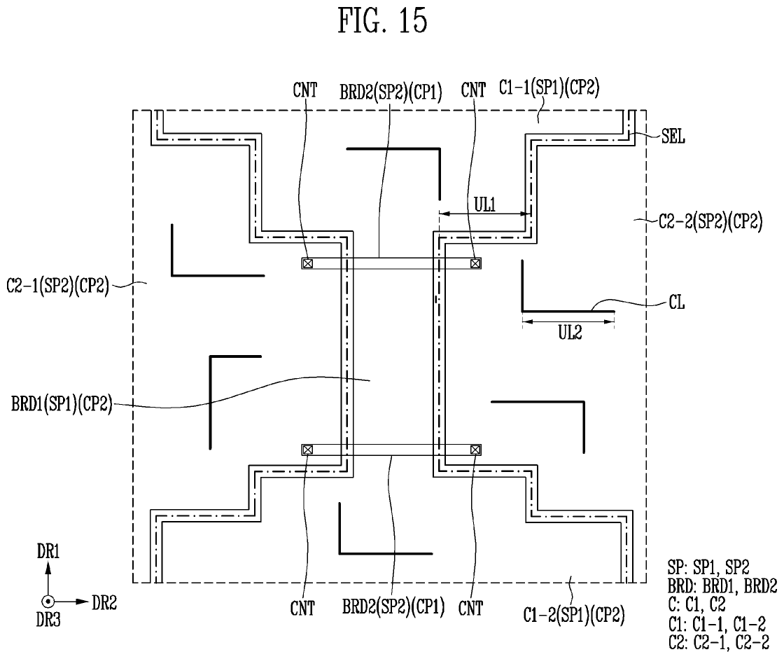

Referring to FIG. 15, the cells C according to some embodiments may comprise a cutting area CL. FIG. 15 is a plan view illustrating the display device DD according to some embodiments, and illustrates the sensing electrodes SP and the cutting area CL.

According to some embodiments, the cutting area CL may be an area in which the first conductive pattern CP1 is disconnected. For example, referring to FIG. 14, the first portions P1 and the second portions P2 may be patterned to form a mesh structure. Here, in an area where the cells C are defined, the first portions P1 and the second portions P2 may be integrally formed, and may be electrically connected to each other. In the area where the cells C are defined, at least some of the first portions P1 and the second portions P2 may be disconnected. For example, a first portion P1 and an adjacent first portion P1 may be spaced apart from each other with the cutting area CL interposed therebetween, and a first portion P1 and an adjacent second portion P2 may be spaced apart from each other.

According to some embodiments, a second unit length UL2 of the cutting area CL may correspond to a first unit length UL1 of the separation line SEL. For example, the cutting area CL may comprise one or more cutting portions each having the second unit length UL2. For example, the cutting area CL may comprise cutting portions, which are formed by bending a portion thereof, and each of which has the second unit length UL2. According to some embodiments, the separation line SEL may comprise two or more separation portions formed by at least a portion thereof in a boundary area between the cells C. According to some embodiments, each of the separation portions may have the first unit length UL1.

According to some embodiments, the cutting area CL having the second unit length UL2 corresponding to the first unit length UL1 is formed in the area where the cells C are formed, so that the visibility can be further enhanced. For example, in the case where only the separation line SEL is partially formed, there is the possibility of deterioration in external visibility due to an uneven electrode arrangement structure. However, in the case where the cutting area CL corresponding to the structure of the separation line SEL is formed in the cells C, light reflection is induced in a manner similar to that of the case where the electrode arrangement structure is substantially uniform. Consequently, the risk of deterioration in external visibility can be reduced.

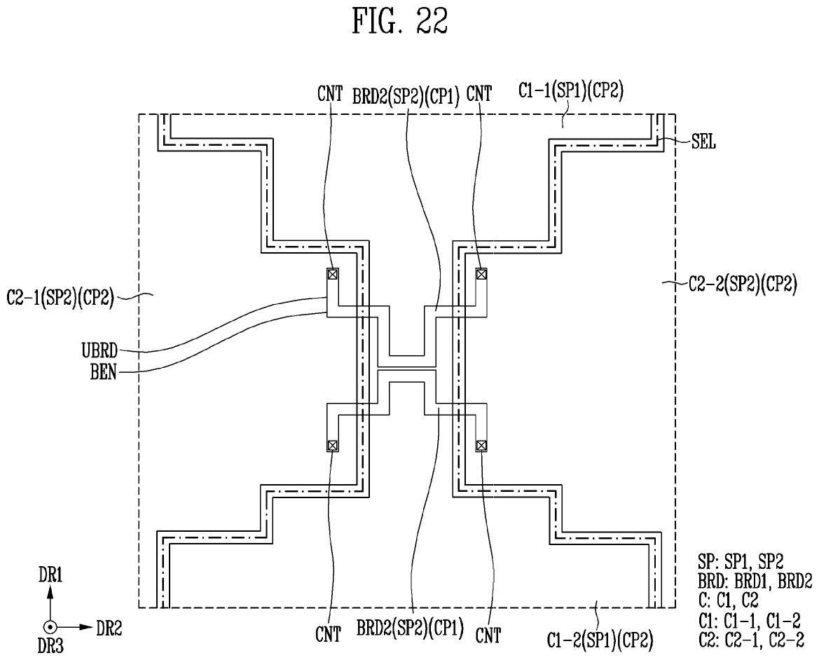

Next, a display device DD according to some embodiments will be described with reference to FIGS. 21 and 22. FIGS. 21 and 22 are schematic views each illustrating the display device DD according to some embodiments. Description overlapping that of the embodiments described above will be simplified, or may not be repeated.

FIG. 21 is a schematic plan view illustrating the display device DD according to some embodiments. FIG. 22 is a schematic plan view illustrating the display device DD according to some embodiments.

The display device DD according to some embodiments is different from the display device DD in accordance with the previous embodiments in that the second bridge BRD2 comprises a bent portion BEN.

According to some embodiments, an area where a unit bridge UBRD is located may overlap an area between the sub-pixels SPX. According to some embodiments, the second bridge BRD2 may comprise two or more unit bridges UBRD extending in different directions based on the bent portion BEN.

For example, the second bridge BRD2 may be bent six times, thus comprising seven unit bridges UBRD. However, the numbers of unit bridges UBRD and bent portions BEN are not particularly limited.

According to some embodiments, the shape of the second bridge BRD2 comprising the unit bridges UBRD may correspond to the shape of the separation line SEL. For example, the shape of the second bridge BRD2 may have a structure in which a central portion thereof protrudes. Likewise, the separation line SEL may have a structure in which a central portion thereof protrudes.

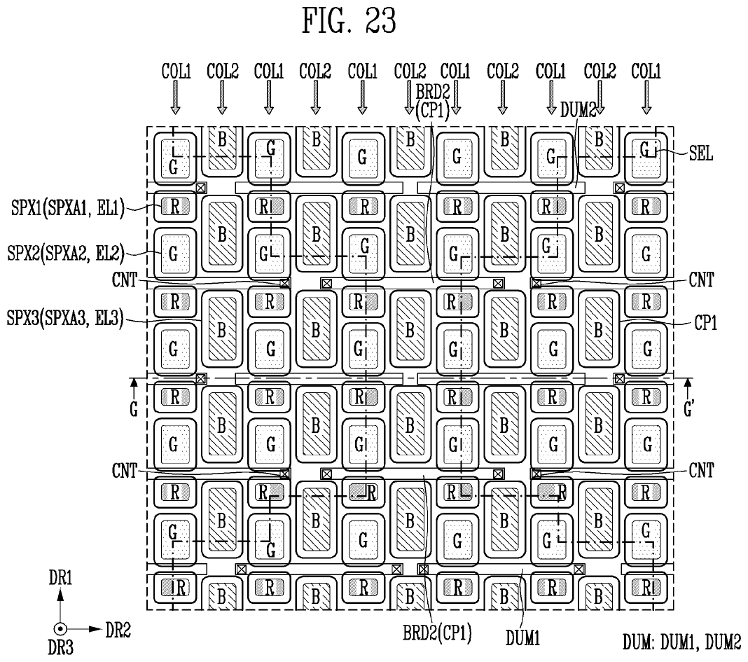

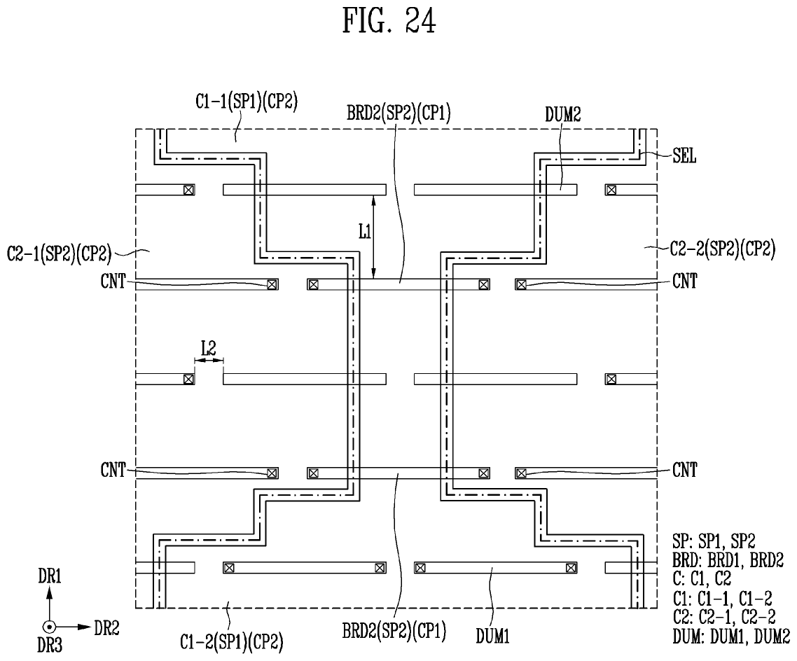

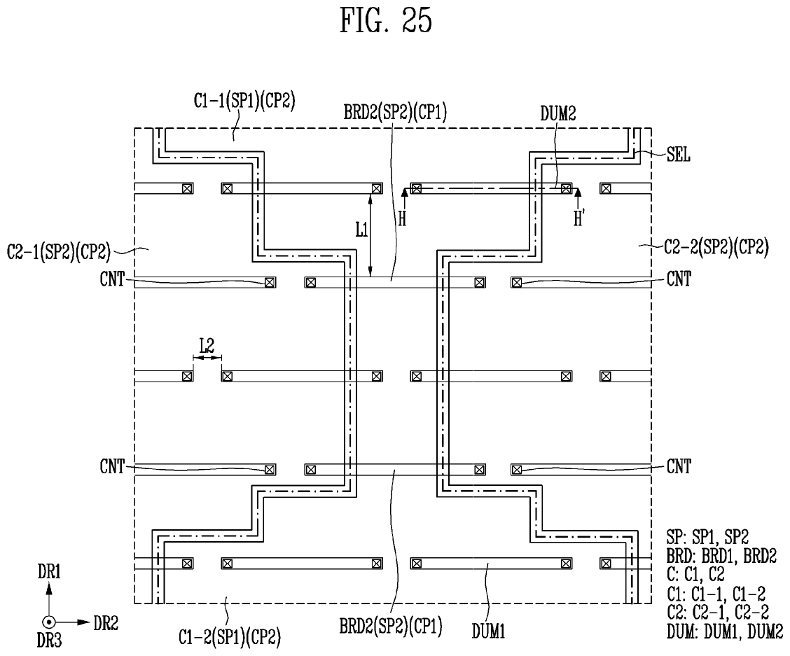

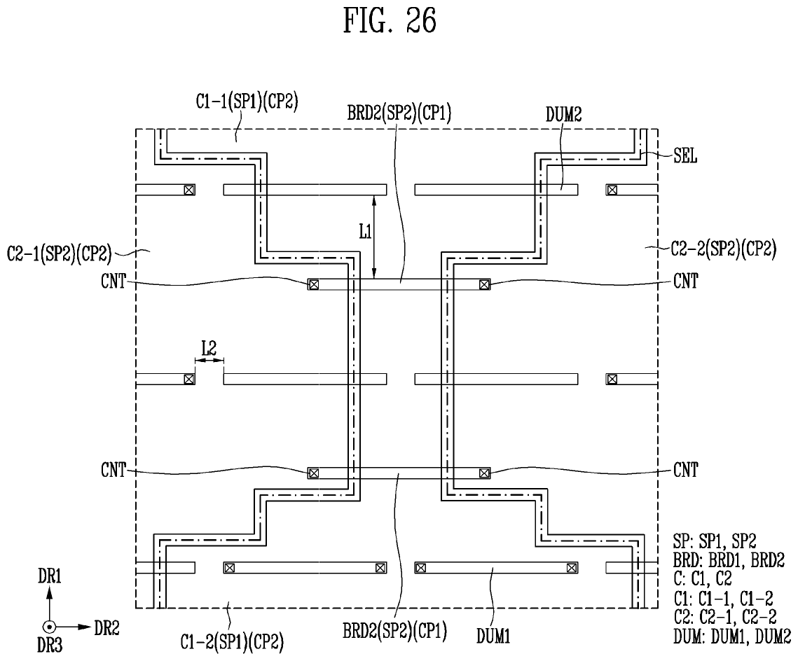

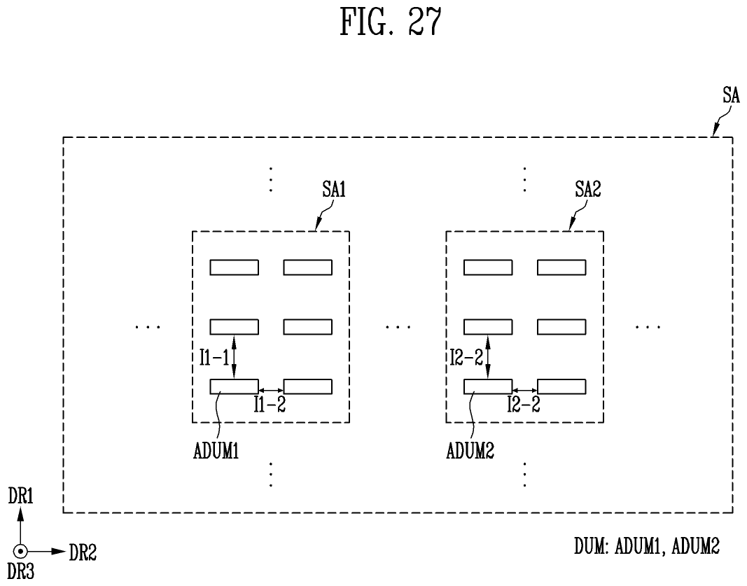

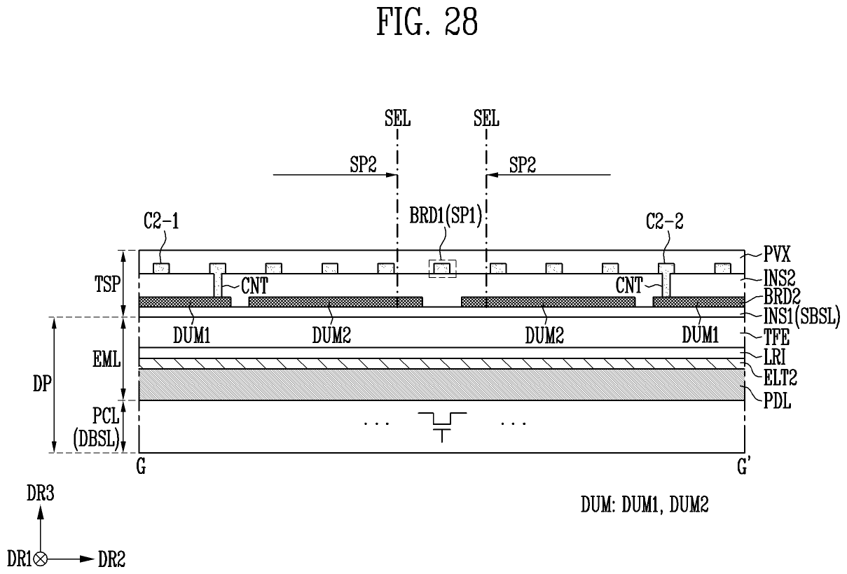

Next, a display device DD according to some embodiments will be described with reference to FIGS. 23 to 29. FIGS. 23 to 29 are schematic views each illustrating the display device DD according to some embodiments. Description overlapping that of the embodiments described above will be simplified, or may not be repeated.

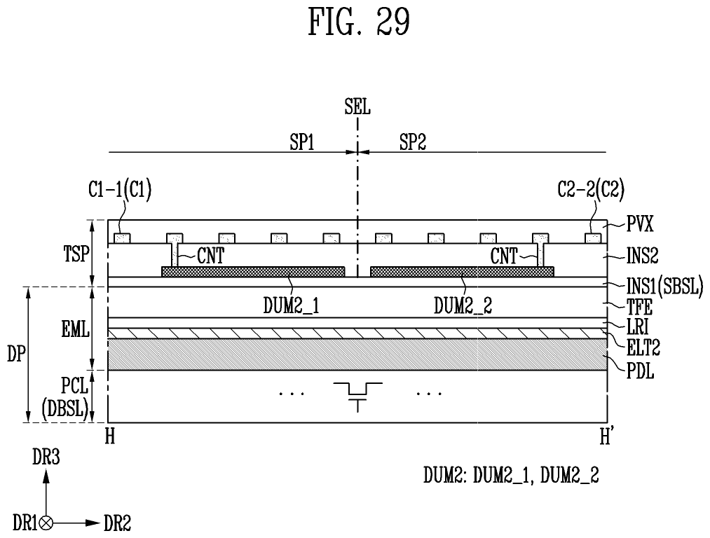

FIGS. 23 to 26 are schematic plan views each illustrating the display device DD according to some embodiments. FIG. 27 is a schematic sectional view for describing a relationship between structures of dummy bridges in the first sensing area and the second sensing area. FIGS. 28 and 29 are schematic sectional views illustrating the display device DD according to some embodiments. FIG. 28 is a schematic sectional view taken along line G-G′ of FIG. 23. FIG. 29 is a schematic sectional view taken along line H-H′ of FIG. 25.

The display device DD according to some embodiments is different from the display device DD in accordance with the previous embodiments in that the display device DD further comprises a dummy bridge DUM.

In the present specification, “dummy bridge” may also be referred to as “auxiliary electrode structure”. For example, the first dummy bridge DUM1 may be referred to as a first auxiliary electrode structure. The second dummy bridge DUM2 may be referred to as a second auxiliary electrode structure.

According to some embodiments, the first conductive pattern CP1 may further form the dummy bridge DUM.

According to some embodiments, the dummy bridge DUM may have an electrode structure arranged to correspond to the shape and/or arrangement structure of the second bridge BRD2 to improve the visibility of the display device DD. According to some embodiments, one or more of a shape, a length, and an extension direction of the dummy bridge DUM may be substantially the same as that of the second bridge BRD2.

According to some embodiments, the dummy bridge DUM may be patterned such that some structure characteristics thereof may correspond to that of the second bridge BRD2. For example, as the dummy bridge DUM is located, one or more among the position of the multilayer area in which both the first conductive pattern CP1 and the second conductive pattern CP2 are arranged in the entirety of the sensing area SA, the surface area of the multilayer area, and the shape of the multilayer area may be substantially uniformly defined. Consequently, the visibility of the display device DD may be relatively enhanced.

For example, the dummy bridge DUM may extend in the same direction (e.g., the second direction DR2) as the second bridge BRD2. The dummy bridge DUM may have substantially the same length as the second bridge BRD2. The dummy bridge DUM may have substantially the same shape as the second bridge BRD2.

According to some embodiments (for example, refer to FIGS. 23 to 25), the distances by which adjacent bridges among the dummy bridges DUM and the second bridges BRD2 are spaced from each other may be substantially the same. For example, first distances L1 between bridges adjacent to each other in the first direction DR1 among the dummy bridges DUM and the second bridges BRD2 may be substantially the same. Second distances L2 between bridges adjacent to each other in the second direction DR2 among the dummy bridges DUM and the second bridges BRD2 may be substantially the same.

For example, the dummy bridges DUM that are adjacent to each other in the first direction DR1, the second bridges BRD2 that are adjacent to each other in the first direction DR1, and the dummy bridge DUM and the second bridge BRD2 that are adjacent to each other in the first direction DR1 each may be spaced apart from each other by a first distance L1. The dummy bridges DUM that are adjacent to each other in the second direction DR2, the second bridges BRD2 that are adjacent to each other in the second direction DR2, and the dummy bridge DUM and the second bridge BRD2 that are adjacent to each other in the second direction DR2 each may be spaced apart from each other by a second distance L2.

According to some embodiments (e.g., refer to FIG. 26), the dummy bridge DUM may not be located in an area adjacent to the second bridge BRD2. For example, the dummy bridge DUM may not be located in the area that is directly adjacent to the second bridge BRD2 in the second direction DR2.

According to some embodiments, the dummy bridges DUM may be arranged in the sensing area SA according to a pattern structure. The dummy bridges DUM may be formed (or patterned) in a repetitive pattern in the sensing area SA according to a preset criterion.

For example, referring to FIG. 27, the dummy bridges DUM may be arranged in a first sensing area SA1, which is a portion in the sensing area SA, according to a first criterion. The dummy bridges DUM may be arranged in a second sensing area SA2, which is another portion in the sensing area SA, according to a second criterion corresponding to (or substantially identical to) the first criterion.

The dummy bridges DUM may comprise first area dummy bridges ADUM1 located in the first sensing area SA1, and second area dummy bridges ADUM2 located in the second sensing area SA2.

According to some embodiments, a pattern structure in which the first area dummy bridges ADUM1 are arranged in the first sensing area SA1 and a pattern structure in which the second area dummy bridges ADUM2 are arranged in the second sensing area SA2 may correspond to each other.

For example, the first area dummy bridges ADUM1 in the first sensing area SA1 are spaced apart from each other in the first direction DR1 by a 1-1-th distance I1-1. The second area dummy bridges ADUM2 in the second sensing area SA2 are spaced apart from each other in the first direction DR1 by a 1-2-th distance I1-2 corresponding to (or substantially identical to) the 1-1-th distance I1-1.

For example, the first area dummy bridges ADUM1 in the first sensing area SA1 are spaced apart from each other in the second direction DR2 by a 1-2-th distance I1-2. The second area dummy bridges ADUM2 in the second sensing area SA2 are spaced apart from each other in the second direction DR2 by a 2-2-th distance I2-2 corresponding to (or substantially identical to) the 1-2-th distance I1-2.

According to some embodiments, because the structure in which the first area dummy bridges ADUM1 in the first sensing area SA1 are arranged and the structure in which the second area dummy bridges ADUM2 in the second sensing area SA2 are arranged correspond to each other, the risk of visual exposure of the dummy bridges DUM and the second bridges BRD2 in the sensing area SA may be reduced.

At least some of the dummy bridges DUM may not be electrically connected to the sensing electrodes SP. A sensing signal may not be applied to at least some of the dummy bridges DUM.

For example, the dummy bridges DUM may comprise a first dummy bridge DUM1 and a second dummy bridge DUM2.

According to some embodiments, the first dummy bridge DUM1 may be located in an internal area of the cell C of the sensing electrode SP. For example, the first dummy bridge DUM1 may not overlap the cell C of another sensing electrode SP adjacent thereto. The first dummy bridge DUM1 may not overlap the separation line SEL in a plan view.

According to some embodiments, at least a portion of the second dummy bridge DUM2 may be located in a peripheral area of the cell C of the sensing electrode SP. For example, the second dummy bridge DUM2 may overlap the cell C of another sensing electrode SP adjacent thereto. The second dummy bridge DUM2 may be located on the first sensing electrode SP1 and the second sensing electrode SP2. The second dummy bridge DUM2 may overlap the separation line SEL in a plan view.

The first dummy bridge DUM1 may be a dummy bridge DUM which is electrically connected to the sensing electrode SP. The first dummy bridge DUM1 may be electrically connected to at least a portion of the first conductive pattern CP1 through a contactor CNT. For example, the first dummy bridge DUM1 may be electrically connected to the 2-1-th cell C2-1. The first dummy bridge DUM1 may be electrically connected to the 2-2-th cell C2-2.

According to some embodiments (e.g., refer to FIGS. 23, 24, and 26), the second dummy bridge DUM2 may not be electrically connected to the second conductive pattern CP2, and thus may be electrically separated from the sensing electrode SP. For example, the contactor CNT may not be formed in the second dummy bridge DUM. The second dummy bridge DUM2 may not overlap the contactor CNT in a plan view. The second dummy bridge DUM2 may not be electrically connected to the contactor CNT that is electrically connected to the second conductive pattern CP2.

According to some embodiments (e.g., refer to FIGS. 25 and 29), at least a portion of the second dummy bridge DUM2 may be electrically connected to the second conductive pattern CP2. According to some embodiments, the second dummy bridge DUM2 may be divided into parts, with the separation line SEL interposed between the parts. Hence, a part of the second dummy bridge DUM2 may be electrically connected to the first sensing electrode SP1, and another part of the second dummy bridge DUM2 may be electrically connected to the second sensing electrode SP2. Furthermore, the first sensing electrode SP1 and the second sensing electrode SP2 may not be electrically connected from each other.

According to some embodiments, the second dummy bridge DUM2 may overlap, on a first end thereof, a contactor CNT in a plan view, and may overlap, on a second end thereof, a contactor CNT in a plan view. For example, the second dummy bridge DUM2 may comprise a 2_1-th dummy bridge DUM2_1 and a 2_2-th dummy bridge DUM2_2. The 2_1-th dummy bridge DUM2_1 and the 2_2-th dummy bridge DUM2_2 may be electrically separated from each other. The 2_1-th dummy bridge DUM2_1 may be electrically connected to the first sensing electrode SP1 (e.g., the first cell C1) through the corresponding contactor CNT. The 2_1-th dummy bridge DUM2_1 may overlap, in a plan view, the contactor CNT that is located in an area in which the first sensing electrode SP1 is formed. The 2_2-th dummy bridge DUM2_2 may be electrically connected to the second sensing electrode SP2 (e.g., the second cell C2) through the corresponding contactor CNT. The 2_2-th dummy bridge DUM2_2 may overlap, in a plan view, the contactor CNT that is located in an area in which the second sensing electrode SP2 is formed.

Hence, in the sensing area SA, contactors CNT may be formed in a first end and a second end of each of the second bridges BRD2, contactors CNT may be formed in a first end and a second end of each of the first dummy bridges DUM1, and contactors CNT may be formed in a first end and a second end of each of the second dummy bridges DUM2. Experimentally, in the case where the contactors CNT are not partially formed in some areas, there is concern about a reduction in visibility. However, according to some embodiments, the contactors CNT may be repeatedly formed (or formed) in the entirety of the sensing area SA, so that the visibility of the display device DD (e.g., the sensing area SA) can be enhanced.

According to some embodiments, the dummy bridge DUM is arranged so that the visibility can be enhanced, and the first dummy bridge DUM1 among the dummy bridges DUM may be electrically connected to the first conductive pattern CP1. In this case, because the resistance of the sensing electrode SP can be reduced, the operation efficiency of the sensor component TSP may be enhanced.

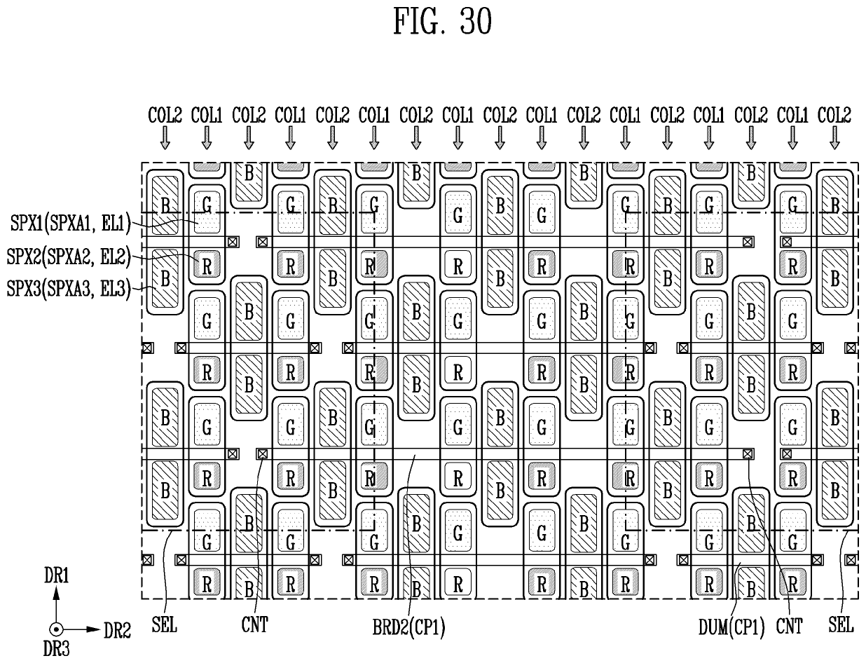

Next, a display device DD according to some embodiments will be described with reference to FIGS. 30 to 32. FIGS. 30 to 32 are schematic views each illustrating the display device according to some embodiments. Description overlapping that of the embodiments described above will be simplified, or may not be repeated.

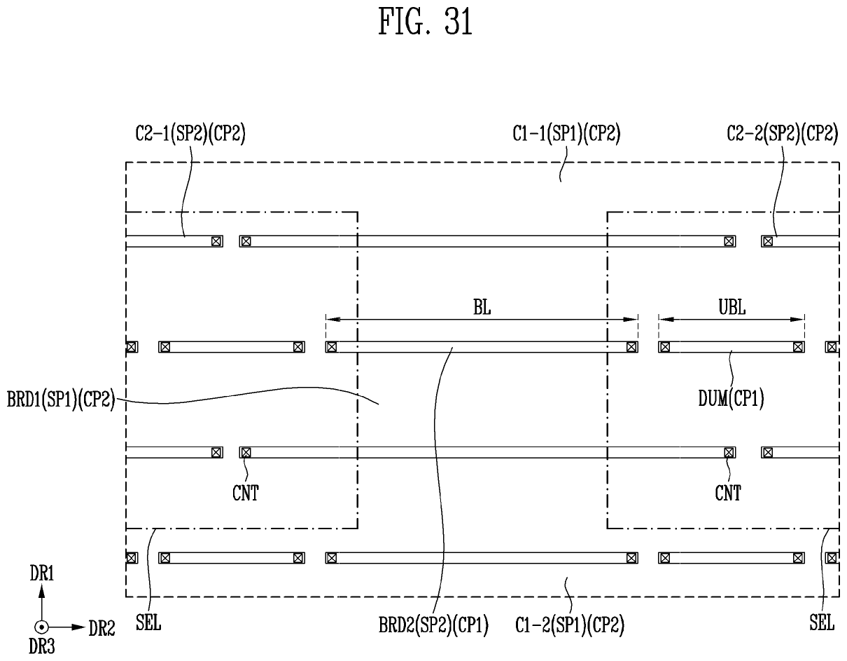

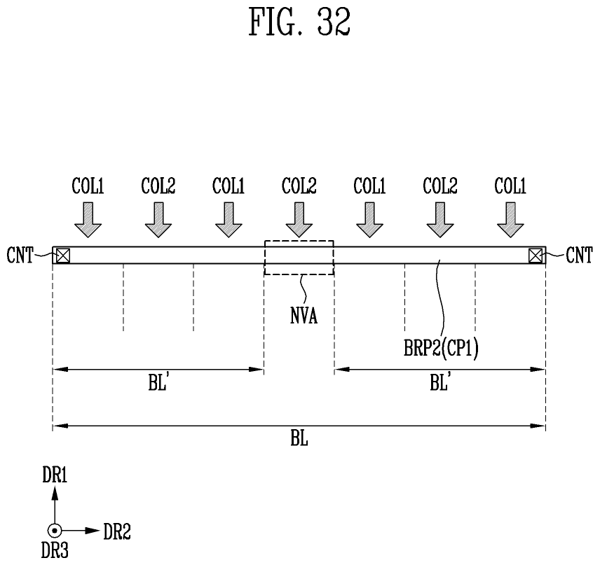

FIGS. 30 and 32 are schematic plan views each illustrating the display device DD according to some embodiments. FIG. 30 illustrates a second bridge BRD2, a dummy bridge DUM, and a sub-pixel area SPXA. FIG. 31 illustrates the second bridge BRD2, the dummy bridge DUM, and sensing electrodes SP. FIGS. 30 and 31 illustrate the same area. FIG. 32 is a diagram for describing length characteristics of the second bridge BRD2.

The display device DD according to some embodiments is different from the display device DD in accordance with the previous embodiments in that the lengths of at least some of the second bridges BRD2 differ from the length of the dummy bridge DUM.

According to some embodiments, the second bridge BRD2 may have a bridge length BL. The dummy bridge DUM may have a dummy length UBL. Each of the bridge length BL and the dummy length UBL may be defined based on the second direction DR2. The bridge length BL may be greater than the dummy length UBL.

According to some embodiments, in the case where the second bridge BRD2 has a length greater than that of the dummy bridge DUM, the bridge pattern may be recognized as being uniformly arranged in the sensing area SA. For example, in the case where the second bridges BRD2 are patterned such that the lengths of some of the second bridges BRD2 in the second direction DR2 are greater than that of other dummy patterns DUM or the other second bridges BRD2, the bridge structures (e.g., the dummy bridges DUM and the second bridges BRD2) may be recognized (or determined) as being arranged to have a repetitive pattern in the sensing area SA.

For example, the second bridge BRD2 may comprise a visibility reducing area NVA. According to some embodiments, the second bridge BRD2 may be located between adjacent third sub-pixel areas SPXA that are spaced apart from each other by a relatively large distance in the visibility reducing area NVA. In this case, the second bridge BRD2 may be spaced apart from the third sub-pixel areas SPXA by a sufficient distance in the visibility reducing area NVA, and may be covered with the second conductive pattern CP2 that is arranged thereover. Hence, a portion of the second bridge that is located in the visibility reducing area NVA may not substantially affect the visibility. Consequently, the second bridge BRD2 may be recognized as having a structure in which two electrodes each having length corresponding a recognition bridge length BL′ that is a length of an area other than the visibility reducing area NVA are located. Here, the recognition bridge length BL′ may correspond to (or be substantially identical to) the dummy length UBL. For example, a portion of the second bridge BRD2 in one side area of the visibility reducing area NVA may overlap two first pixel columns COL1 and one second pixel column COL2 in the first direction DR1. The dummy bridge DUM may also two first pixel columns COL1 and one second pixel column COL2 in the first direction DR1.

Therefore, according to some embodiments, the structure of the second bridge BRD2 that expands in some areas may be implemented, and the display device DD having enhanced visibility may be provided in the same manner as that of the previous embodiments.

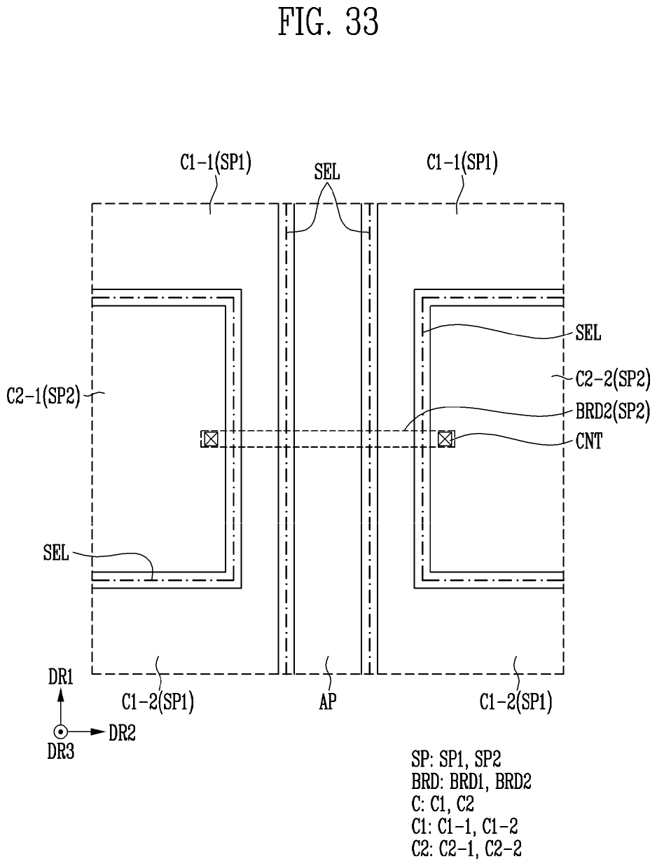

Next, a display device DD according to some embodiments will be described with reference to FIGS. 33 to 35. FIGS. 33 to 35 are schematic views each illustrating the display device according to some embodiments. Description overlapping that of the embodiments described above will be simplified, or may not be repeated.

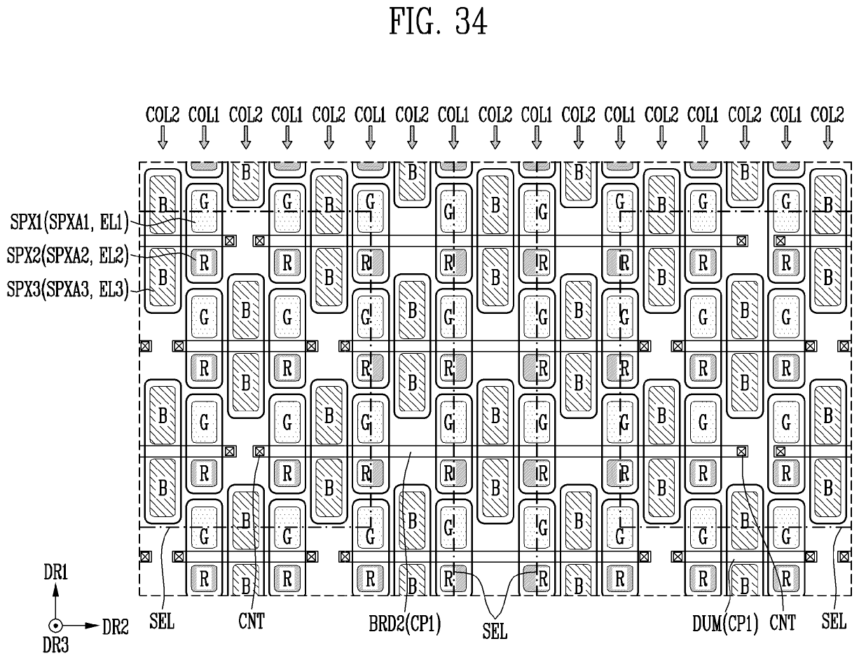

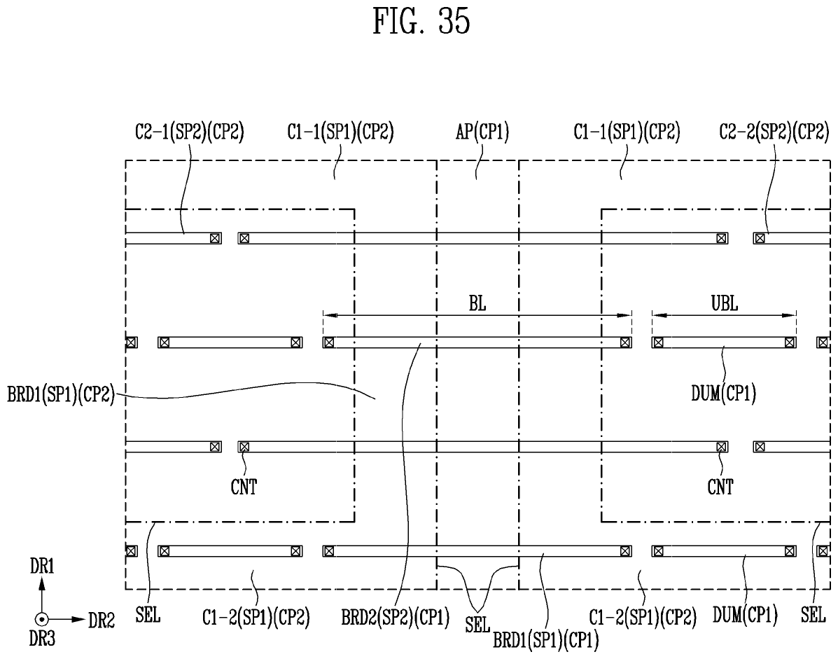

FIGS. 33 to 35 are schematic plan views each illustrating the display device DD according to some embodiments. FIG. 33 is a schematic plan view for describing a structure in which the sensing component TSP further comprises an additional electrode AP. FIG. 34 illustrates a second bridge BRD2, a dummy bridge DUM, and a sub-pixel area SPXA. FIG. 35 illustrates the second bridge BRD2, the dummy bridge DUM, and sensing electrodes SP. FIGS. 34 and 35 illustrate the same area.

The display device DD according to some embodiments is different from the display device DD in accordance with the previous embodiments in that the display device DD further comprises an additional electrode AP.

According to some embodiments, the sensing component TSP may further comprise an additional electrode AP. The additional electrode AP may be formed of the second conductive pattern CP2. For example, the additional electrode AP may be located in the same layer as the first cell C1 and the second cell C2.

According to some embodiments, the additional electrode AP may be adjacent to the first sensing electrode SP1 and the second sensing electrode SP2 with the separation line SEL interposed therebetween.

The additional electrode AP may be located between the first sensing electrodes SP1 adjacent to each other. For example, the additional electrode AP may be located between the 1-1-th cells C1-1 adjacent to each other in the second direction DR2. The additional electrode AP may be located between the 1-2-th cells C1-2 adjacent to each other in the second direction DR2.

The additional electrode AP may be located between the second sensing electrodes SP2 adjacent to each other. For example, the additional electrode AP may be located between the 2-1-th cell C2-1 and the 2-2-th cell C2-2 adjacent to each other in the second direction DR2.

The additional electrode AP may extend in the first direction DR1. According to some embodiments, the additional electrode AP may be electrically separated from the first sensing electrode SP1 and the second sensing electrode SP2. The additional electrode AP may be supplied with an electrical signal different from the first sensing signal to be supplied to the first sensing electrode SP1 or the second sensing signal to be supplied to the second sensing electrode SP2. For example, the additional electrode AP may be supplied with a noise sensing signal for enhancing the sensing performance in the sensing area SA.

According to some embodiments, the additional electrode AP may overlap the second bridge BRD2 in a plan view. For example, at least a portion of the second bridge BRD2 may extend in the second direction DR2, and may be arranged to intersect the additional electrode AP.

According to some embodiments, the additional electrode AP may not be electrically connected to the second bridge BRD2. The second bridge BRD2 may extend in the second direction DR2, and may electrically connect the 2-1-th cell C2-1 and the 2-2-th cell C2-2 spaced apart from each other by the first sensing electrode SP1 and the additional electrode AP.

In a manner similar to that described above, aspects of some embodiments may include a display device DD having relatively enhanced visibility, thanks to structural characteristics of the second bridge BRD2 and the dummy bridge DUM with regard to the arrangement of the sub-pixel area SPXA.

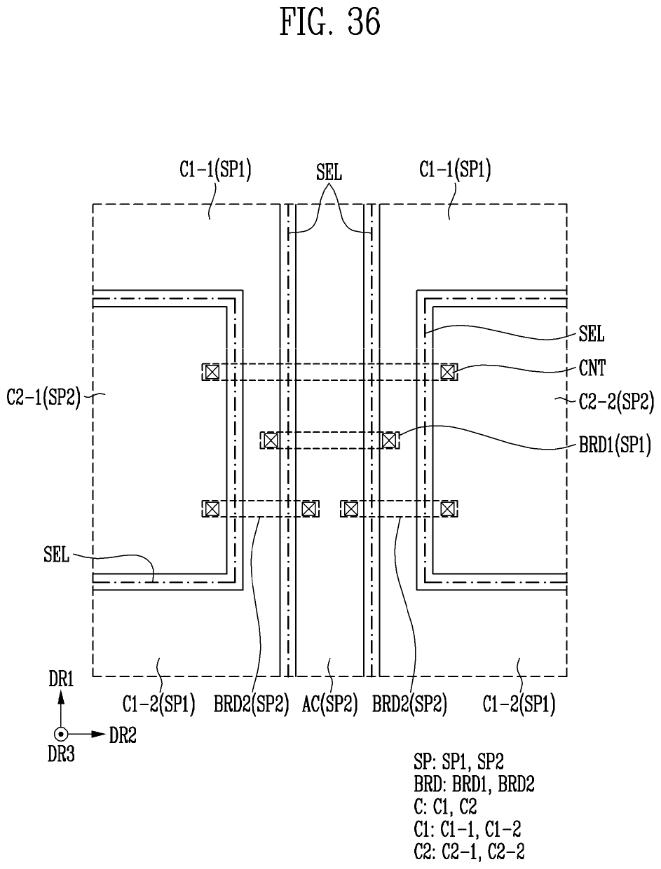

Next, a display device DD according to some embodiments will be described with reference to FIGS. 36 to 38. FIGS. 36 to 38 are schematic views each illustrating the display device according to some embodiments. Description overlapping that of the embodiments described above will be simplified, or may not be repeated.

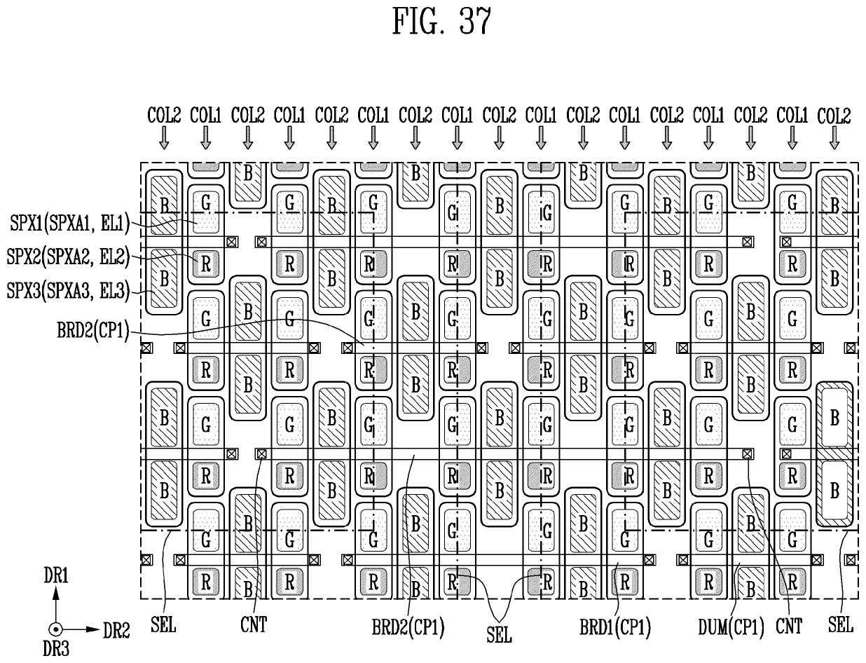

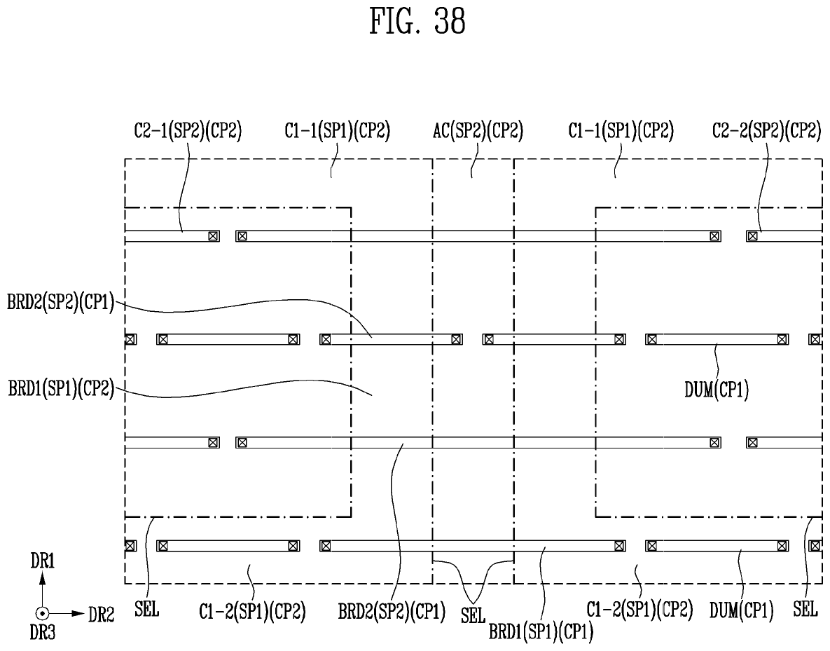

FIGS. 36 to 38 are schematic plan views each illustrating the display device DD according to some embodiments. FIG. 36 is a schematic plan view for describing a structure in which the sensing component TSP further comprises an additional sensing electrode AC. FIG. 37 illustrates a second bridge BRD2, a dummy bridge DUM, and a sub-pixel area SPXA. FIG. 38 illustrates the second bridge BRD2, the dummy bridge DUM, and sensing electrodes SP. FIGS. 37 and 38 illustrate the same area.

The display device DD according to some embodiments is different from other embodiments in that the additional sensing electrode AC is formed at a position corresponding to (or substantially identical to) the additional electrode AP according to some embodiments.

According to some embodiments, the sensing component TSP may further comprise an additional sensing electrode AC. The additional sensing electrode AC may be formed of the second conductive pattern CP2. For example, the additional sensing electrode AC may be located in the same layer as the first cell C1 and the second cell C2.

According to some embodiments, the additional sensing electrode AC may be adjacent to the first sensing electrode SP1 and the second sensing electrode SP2 with the separation line SEL interposed therebetween. For example, the additional sensing electrode AC may be directly adjacent to the first sensing electrode SP1, and may be adjacent to the second sensing electrode SP2 with the first sensing electrode SP1 interposed therebetween.

The additional sensing electrode AC may be located between the first sensing electrodes SP1 adjacent to each other. For example, the additional sensing electrode AC may be located between the 1-1-th cells C1-1 adjacent to each other in the second direction DR2. The additional sensing electrode AC may be located between the 1-2-th cells C1-2 adjacent to each other in the second direction DR2.

The additional sensing electrode AC may be located between the second sensing electrodes SP2 adjacent to each other. For example, the additional sensing electrode AC may be located between the 2-1-th cell C2-1 and the 2-2-th cell C2-2 adjacent to each other in the second direction DR2. The additional sensing electrode AC may extend in the first direction DR1. The additional sensing electrode AC may be electrically connected to the first sensing electrodes SP1. According to some embodiments, the additional sensing electrode AC may be supplied with a sensing signal identical to the first sensing signal to be supplied to the first sensing electrode SP1. For example, the additional sensing electrode AC may function as the same electrode as the first sensing electrodes SP1. According to some embodiments, in the case where the first sensing electrode SP1 is a Tx pattern electrode, the additional sensing electrode AC may also be a Tx pattern electrode. In the case where the first sensing electrode SP1 is an Rx pattern electrode, the additional sensing electrode AC may also be an Rx pattern electrode.

According to some embodiments, the additional sensing electrode AC may overlap the second bridge BRD2 in a plan view. For example, at least a portion of the second bridge BRD2 may extend in the second direction DR2, and may be arranged to intersect the additional sensing electrode AC.

According to some embodiments, the additional sensing electrode AC may be electrically connected to the second bridge BRD2. For example, the second bridge BRD2 may extend in the second direction DR2, and may electrically connect the additional sensing electrode AC and the 2-1-th cell C2-1 to each other. The second bridge BRD2 may extend in the second direction DR2, and may electrically connect the additional sensing electrode AC and the 2-2-th cell C2-2 to each other. However, the disclosure is not limited to the foregoing. For example, the second bridge BRD2 may extend in the second direction DR2, and may electrically connect the 2-1-th cell C2-1 and the 2-2-th cell C2-2 to each other, without being electrically connected to the additional sensing electrode AC.

According to some embodiments, the additional sensing electrode AC may overlap at least a portion of the first bridge BRD1 formed of the first conductive pattern CP1 in a plan view. For example, at least a portion of the first bridge BRD1 may extend in the second direction DR2, and may be arranged to intersect the additional sensing electrode AC.

According to some embodiments, the additional sensing electrode AC may not be electrically connected to the first bridge BRD1. The first bridge BRD1 may extend in the second direction DR2, and may electrically connect a portion and another portion of the 1-1-th cell C1-1 that are spaced apart from each other by the additional sensing electrode AC. The first bridge BRD1 may extend in the second direction DR2, and may electrically connect a portion and another portion of the 1-2-th cell C1-2 that are spaced apart from each other by the additional sensing electrode AC.

In a manner similar to that described above, aspects of some embodiments may include a display device DD having relatively enhanced visibility, thanks to structural characteristics of the second bridge BRD2 and the dummy bridge DUM with regard to the arrangement of the sub-pixel area SPXA. For example, according to some embodiments, an adjacent surface between an electrode to be supplied with a first sensing signal and an electrode to be supplied with a second sensing signal may be further expanded, and the bridge structure connected with the structure of the sub-pixel area SPXA may form a precisely electrical connection structure, so that the visibility reduction risk can be substantially reduced.

Various embodiments according to the present disclosure may provide a display device having relatively improved visibility.

While various embodiments have been described above, those skilled in the art will appreciate that various modifications, additions and substitutions are possible, without departing from the scope and spirit of the disclosure.

Therefore, the embodiments disclosed in this specification are only for illustrative purposes rather than limiting the technical spirit of the disclosure. The scope of the disclosure must be defined by the accompanying claims, and their equivalents.

What is claimed is:

1. A display device comprising:
a display component on a base layer, and provided to form a plurality of pixels comprising a first pixel and a second pixel; and
a sensor component on the display component, and comprising conductive patterns comprising a first conductive pattern and a second conductive pattern,
wherein each of the plurality of pixels comprises sub-pixels comprising:
a first sub-pixel forming a first sub-pixel area configured to emit a first color of light;
a second sub-pixel forming a second sub-pixel area configured to emit a second color of light; and
a third sub-pixel forming a third sub-pixel area configured to emit a third color of light,
wherein the first pixel and the second pixel are adjacent to each other along a first direction,
wherein the third sub-pixel of the first pixel is adjacent to the third sub-pixel of the second pixel along the first direction,
wherein the first sub-pixel and the second sub-pixel of the first pixel are adjacent to the first sub-pixel and the second sub-pixel of the second pixel along the first direction,
wherein each of the conductive patterns comprises a first sensing electrode and a second sensing electrode,
wherein the first sensing electrode comprises first cells, and a first bridge electrically connecting the first cells,
wherein the second sensing electrode comprises second cells, and a second bridge electrically connecting the second cells, and
wherein a portion of the second bridge is between the third sub-pixel of the first pixel and the third sub-pixel of the second pixel, and another portion of the second bridge is between the second sub-pixel of the first pixel and the first sub-pixel of the second pixel.

2. The display device according to claim 1,
wherein the second conductive pattern comprises first portions and a second portion, and
wherein each of the first portions forms a loop enclosing one or more of the sub-pixels, and the second portion connects the first portions to each other.

3. The display device according to claim 2, wherein the second bridge overlaps the second portion, in a plan view.

4. The display device according to claim 1,
wherein the second bridge is electrically connected to the second conductive pattern through a contactor, and
wherein the contactor overlaps the third sub-pixel in the first direction.

5. The display device according to claim 4, wherein the second bridge passes between the first sub-pixel and the second sub-pixel, and passes between the second sub-pixel of the first pixel and the second sub-pixel of the first pixel.

6. The display device according to claim 1, wherein at least a portion of the second bridge extends in a second direction different from the first direction.

7. The display device according to claim 1, wherein an entirety of an end of the first conductive pattern is covered with an end of the second conductive pattern, in a plan view.

8. The display device according to claim 7, wherein a first width of a portion of the second conductive pattern that does not overlap the first conductive pattern is less than a second width of another portion of the second conductive pattern that overlaps the first conductive pattern.

9. The display device according to claim 1, wherein a surface area of the third sub-pixel area is greater than a surface area of the first sub-pixel area or a surface area of the second sub-pixel area.

10. The display device according to claim 9, wherein the third sub-pixels for the respective sub-pixels are spaced apart from each other at regular intervals along the first direction.

11. The display device according to claim 9, wherein the third sub-pixels are spaced apart from each other by a first distance in a first area, and other third sub-pixels are spaced apart from each other by a second distance greater than the first distance in a second area adjacent to the first area in the first direction.

12. The display device according to claim 11,
wherein the second bridge is electrically connected to the first conductive pattern through a contactor, and
wherein the contactor is in the second area.

13. The display device according to claim 1, wherein the second bridge comprises a bent portion, and one or more unit bridges extending in different directions and arranged between the sub-pixels.

14. The display device according to claim 13,
wherein the first sensing electrode and the second sensing electrode are spaced apart from each other with a separation line interposed therebetween, and
wherein a shape formed by the unit bridges corresponds to a shape of the separation line.

15. The display device according to claim 1, wherein the first conductive pattern forms dummy bridges each of which is identical in one or more of shape, length, and/or extension direction to the second bridge.

16. The display device according to claim 15, wherein distances by which adjacent bridges among the dummy bridges and the second bridge are spaced apart from each other along the first direction are identical to each other.

17. The display device according to claim 15, wherein the length of each of the dummy bridges is different from the length of the second bridge.

18. The display device according to claim 17,
wherein the second bridge comprises a visibility reducing area, and
wherein a portion of the second bridge in the visibility reducing area overlaps the third sub-pixel in the first direction.

19. The display device according to claim 18,
wherein the second bridge has a recognition bridge length in one side area of the visibility reducing area,
wherein each of the dummy bridges has a dummy length, and
wherein the recognition bridge length and the dummy length correspond to each other.

20. The display device according to claim 15, further comprising an additional electrode in a same layer as the first cells and the second cells, and extending in the second direction, and located in the first cells,
wherein the additional electrode is electrically separated from the first sensing electrode and the second sensing electrode.

21. The display device according to claim 20, wherein the second bridge overlaps the additional electrode in a plan view, and is electrically separated from the additional electrode.

22. The display device according to claim 15, further comprising an additional sensing electrode in a same layer as the first cells and the second cells, and extending in the second direction, and located in the first cells,
wherein the additional sensing electrode is electrically connected to the second sensing electrode.

23. The display device according to claim 22, wherein the second bridge electrically connects some of the first cells and the additional sensing electrode to each other.

24. The display device according to claim 15,
wherein the dummy bridge comprises a first dummy bridge and a second dummy bridge,
wherein the first dummy bridge is in an internal area of one of the first sensing electrode or the second sensing electrode, and
wherein the second dummy bridge is on the first sensing electrode and the second sensing electrode.

25. The display device according to claim 24,
wherein the first dummy bridge is electrically connected to the second conductive pattern, and
wherein the second dummy bridge is electrically separated from the second conductive pattern.

26. The display device according to claim 24,
wherein the second dummy bridge comprises a 2_1-th dummy bridge and a 2_2-th dummy bridge that are electrically separated from each other, and
wherein the 2_1-th dummy bridge is electrically connected to the first sensing electrode, and the 2_2-th dummy bridge is electrically connected to the second sensing electrode.

27. The display device according to claim 24,
wherein the first conductive pattern and the second conductive pattern are electrically connected to each other through a contactor,
wherein the first sensing electrode and the second sensing electrode are in a sensing area, and
wherein the contactor comprises contactors repeatedly arranged in the sensing areas, the contactors being respectively formed in first and second sides of the first dummy bridge, first and second sides of the second dummy bridge, first and second sides of the second dummy bridge, and first and second sides of the second bridge.

28. The display device according to claim 1, further comprising a cutting area in which at least a portion of the second conductive pattern is cut, in an area where the first cell or the second cell is formed.

29. A display device comprising:
a pixel formed on a base layer, and comprising a first sub-pixel configured to emit a first color of light, a second sub-pixel configured to emit a second color of light, and a third sub-pixel configured to emit a third color of light; and
a sensor component comprising a conductive pattern comprising a first conductive pattern and a second conductive pattern on the first conductive pattern,
wherein the first sub-pixel and the second sub-pixel are alternately arranged along a first direction to form a first pixel column,
wherein the second sub-pixel is successively arranged along the first direction to form a second pixel column,
wherein the first pixel column and the second pixel column are alternately arranged along a second direction different from the first direction,
wherein the conductive pattern form sensing electrodes,
wherein the first conductive pattern is more adjacent to the base layer than the second conductive pattern,
wherein the sensing electrodes comprise cells formed by the second conductive pattern, and a bridge formed by the first conductive pattern and configured to electrically connect the cells to each other,
wherein the third sub-pixel comprises third sub-pixels adjacent to each other, and
wherein the bridge extends, in a plan view, in the first direction between the third sub-pixels adjacent to each other and between the first sub-pixel and the second sub-pixel.

30. A display device comprising:
a display component formed on a base layer, and provided with a plurality of pixels comprising a first pixel and a second pixel; and
a sensor component on the display component, and comprising conductive patterns comprising a first conductive pattern and a second conductive pattern,
wherein the conductive pattern comprises a first sensing electrode, a second sensing electrode, and a dummy bridge,
wherein the first sensing electrode comprises first cells, and a first bridge electrically connecting the first cells,
wherein the second sensing electrode comprises second cells, and a second bridge electrically connecting the second cells,
wherein the first sensing electrode and the second sensing electrode are in a sensing area, and
wherein the dummy bridge is formed in a repetitive pattern in the sensing area according to a preset criterion.

31. The display device according to claim 30,
wherein the sensing area comprises a first sensing area and a second sensing area,
wherein the dummy bridge comprises first area dummy bridges and second area dummy bridges,
wherein the first area dummy bridges are in the first sensing area according to a first criterion,
wherein the second area dummy bridges are in the second sensing area according to a second criterion, and
wherein the first criterion and the second criterion correspond to each other.

32. The display device according to claim 31,
wherein the first area dummy bridges adjacent to each other along a first direction are spaced apart from each other in the first direction by a 1-1-th distance, and
wherein the second area dummy bridges adjacent to each other along the first direction are spaced apart from each other in the first direction by a 1-2-th distance corresponding to the 1-1-th distance.

33. The display device according to claim 32,
wherein the first area dummy bridges adjacent to each other in a second direction different from the first direction are spaced apart from each other by a 1-2-th distance in the second direction, and
wherein the second area dummy bridges adjacent to each other in the second direction are spaced apart from each other in the second direction by a 2-2-th distance corresponding to the 1-2-th distance.

34. The display device according to claim 30,
wherein each of the plurality of pixels comprises sub-pixels comprising: a first sub-pixel forming a first sub-pixel area from which a first color of light is provided; a second sub-pixel forming a second sub-pixel area from which a second color of light is provided; and a third sub-pixel forming a third sub-pixel area from which a third color of light is provided,
wherein the first pixel and the second pixel are adjacent to each other along a first direction,
wherein the third sub-pixel of the first pixel is adjacent to the third sub-pixel of the second pixel along the first direction,
wherein the first sub-pixel and the second sub-pixel of the first pixel are adjacent to the first sub-pixel and the second sub-pixel of the second pixel along the first direction,
wherein the second bridge passes between the first sub-pixel and the second sub-pixel, and passes between the second sub-pixel of the first pixel and the second sub-pixel of the first pixel.

35. The display device according to claim 34,
wherein a surface area of the third sub-pixel area is greater than a surface area of the first sub-pixel area or a surface area of the second sub-pixel area, and
wherein the third sub-pixels are spaced apart from each other by a first distance in a first area, and other third sub-pixels are spaced apart from each other by a second distance greater than the first distance in a second area adjacent to the first area in the first direction.

36. The display device according to claim 35,
wherein an entirety of an end of the first conductive pattern is covered with an end of the second conductive pattern, in a plan view, and
wherein a first width of a portion of the second conductive pattern that does not overlap the first conductive pattern is less than a second width of another portion of the second conductive pattern that overlaps the first conductive pattern.

37. The display device according to claim 35, wherein the dummy bridge is identical in one or more of shape, length, and/or extension direction to the second bridge.

38. The display device according to claim 37, wherein the length of the dummy bridge and the length of the second bridge are different from each other.

39. The display device according to claim 37,
wherein the second bridge comprises a visibility reducing area, and
wherein a portion of the second bridge in the visibility reducing area overlaps the third sub-pixel in the first direction.

40. The display device according to claim 39,
wherein the second bridge has a recognition bridge length in one side area of the visibility reducing area,
wherein the dummy bridge has a dummy length, and
wherein the recognition bridge length and the dummy length correspond to each other.
